(19) United States
(12) Patent Application Publication
(10) Pub. No.: US 2023/0232641 A1
(43) Pub. Date: Jul. 20, 2023

(54) Carbon Nanotube Field-Effect Transistors And Related Manufacturing Techniques

(71) Applicant: Massachusetts Institute of Technology, Cambridge, MA (US)

(72) Inventors: Max SHULAKER, San Mateo, CA (US); Mindy BISHOP, Waltham, MA (US)

(73) Assignee: Massachusetts Institute of Technology, Cambridge, MA (US)

(21) Appl. No.: 18/002,495

(22) PCT Filed: Aug. 20, 2021
(86) PCT No.: PCT/US2021/046964

§ 371 Date: Dec. 20, 2022

Related U.S. Application Data
(60) Provisional application No. 63/068,022, filed on Aug. 20, 2020.

(51) Int. Cl. H10K 10/46; H10K 85/20; H10K 71/12; H10K 71/40

(52) U.S. Cl. CPC H10K 10/484; H10K 85/221; H10K 10/466; H10K 71/12; H10K 71/441

(57) ABSTRACT

Described are concepts, systems, circuits, devices, structures and methods for depositing carbon nanotubes (CNTs) uniformly over a substrate. The described concepts, systems, circuits, devices, structures and methods meet at least several requirements; namely, the systems, circuits, devices, structures are: (1) manufacturable; (2) silicon-CMOS compatible; and (3) provide a path for realizing energy efficiency benefits utilizing silicon. In embodiments, described is an illustrative CNT solution-based deposition technique that addresses all of these requirements. Also described is a method for providing carbon nanotube field effect transistors (CNFETs) using uniform and reproducible fabrication techniques suitable for use across industry-standard wafers and which may use the same equipment currently being used to fabricate silicon product wafers. Also described are CNFETs fabricated within commercial silicon manufacturing facilities and having wafer-scale uniformity and reproducibility across multiple wafers.

### CROSS-REFERENCE TO RELATED APPLICATIONS

This application claims the benefit of U.S. Provisional Application No. 63/068,022 filed Aug. 20, 2020 the entire contents of which is hereby incorporated herein by reference in its entirety.

### GOVERNMENT RIGHTS

This invention was made with Government support under Grant No. HR0011-18-3-0006 awarded by the Defense Advanced Research Projects Agency (DARPA). The Government has certain rights in the invention.

### BACKGROUND

As is known in the art, carbon nanotube (CNT) field-effect transistors (CNFETs) are a nanotechnology which may be used in energy-efficient computing applications. Despite rapid progress, CNFETs have only been realized in academic or research laboratories. One challenge in transferring CNFETs into commercial manufacturing facilities has been developing a method for depositing CNTs uniformly over industry-standard 200 mm substrates, as it should meet several requirements: it should be manufacturable, silicon-CMOS compatible, and provide a path for realizing energy efficiency benefits over silicon.

For decades, physical and equivalent scaling of silicon field-effect transistors (FETs) has driven progress in computing by providing energy-efficiency gains (Dennard Scaling) with simultaneous reduction in cost-per-FET. This has been enabled by continued improvements in commercial semiconductor manufacturing, such as the ability to pattern increasingly smaller features across increasingly large substrates (from <50 mm diameter wafers in the 1970s up to industry-standard 200-300 mm wafers today). Unfortunately, continued scaling of silicon-based FETs no longer provides its historical gains in energy-efficiency. This has spurred work in emerging nanotechnologies to supplement existing silicon complementary-metal-oxide-semiconductor (CMOS) technology.

### SUMMARY OF DISCLOSED EMBODIMENTS

Disclosed are concepts, systems and techniques directed toward control of carbon nanotube deposition over a wafer. Such concepts, systems and techniques may be achieved by changing the concentration of the carbon nanotube solution, the temperature, the incubation time, etc. Such concepts, systems and techniques provide a feasible and scalable approach for carbon nanotube (CNT) deposition.

In accordance with one aspect of the concepts described herein, a CNT incubation methodology referred to herein as “dry-cycling” incubation leverages a CNT drying process to reduce desorption rate and tilt the balance in favor of faster deposition. In embodiments, to perform dry-cycling incubation, substrates are submerged into a CNT solution and incubated for a period of time. The substrates are then removed from the solution, rinsed with a solvent spray, and dried with nitrogen. This process (a “single-cycle” incubation) may be applied once or may be repeated multiple times.

With this particular arrangements, a CNT having a linear density greater than that achievable with prior art techniques,

In embodiments, intermittent drying may be used. The intermittent drying may result in increases in CNT deposition (and in some embodiments, dramatic increases in CNT deposition). Significantly, CNFET electrical performance is not negatively impacted by the number of dry-cycling intervals.

In accordance with another aspect of the concepts described herein, a CNT incubation methodology referred to herein as Artificial Concentration through Evaporation (ACE) may be implemented by depositing a volume of solution on a substrate surface in a controlled manner. Over time, the solvent slowly evaporates from the CNT solution, artificially increasing the concentration of CNTs beyond the starting concentration. By artificially concentrating the CNTs on the wafer surface, the adsorption rate increases, resulting in increased CNT density for any starting CNT solution concentration. Thus, the ACE approach may include an increased CNT deposition rate through an increased rate of adsorption.

CNTs are a leading candidate material for realizing beyond-silicon field effect transistors (FETs). To realize a carbon nanotube field-effect transistor (CNFET), multiple CNTs in parallel comprise a channel of the FET having source, drain, and gate regions. Owing to the ultra-thin body of a CNT (˜1.2 nm diameter, forming a one-dimensional semiconductor) with its simultaneously high carrier transport, digital very-large-scale-integrated (VLSI) circuits fabricated from CNFETs are projected to achieve an order of magnitude improvement in energy-delay product (EDP, a metric of energy efficiency) compared with the EDP of silicon-based FETs. Moreover, CNFETs are a rapidly maturing technology as complete CNFET CMOS digital systems (such as a 16-bit RISC-V microprocessor) as well highly-scaled and high-performance CNFETs have been demonstrated.

Despite this exciting progress, all carbon nanotube field-effect transistor (CNFET) demonstrations to-date have been limited to academic and research laboratories. As progress continues, the technology transfer of CNFETs into commercial semiconductor manufacturing facilities is a critical and necessary step in realizing their future promise. However, initial technology transfer presents major obstacles as all materials and processes used to fabricate CNFETs should meet the strict compatibility requirements of silicon-based commercial fabrication facilities.

While recent works have developed process steps for fabricating complementary CNFETs in a silicon-CMOS compatible fashion, in accordance with the concepts described herein, one remaining challenge is more fundamental: namely, how to uniformly deposit CNTs over industry-standard substrate sizes (e.g. wafers having diameters in the range of about 200 mm- to about 300 mm or greater).

Thus, in accordance with one aspect of the concepts described herein, it has been recognized that for technology transfer to industry, a CNT deposition technique should meet at least three requirements. First, the CNT deposition technique should meet a manufacturability requirement; namely: the CNT deposition technique should be wafer-scalable and provide high-throughput while reducing (and ideally minimizing) cost. Second, the CNT deposition technique should meet a compatibility requirement; namely: the CNT deposition technique should leverage existing equipment and not introduce prohibited chemical contaminants or particulates. Third, the CNT deposition technique should meet a performance requirement; namely: the technique should enable a CNFET technology that can compete with (and eventually surpass) the performance of silicon-based FETs at comparable geometries.

Thus, in accordance with the concepts described herein, techniques to uniformly deposit CNTs over a substrate are described. The described CNT deposition techniques meet all of the aforementioned requirements. In embodiments, the substrate may be provided as an industry-standard substrate (e.g. substrates on which may be provided wafers having a diameter of about 200 mm and above).

The use of an incubation technique (e.g., a solution-based CNT deposition technique) to allow CNTs to adhere to a substrate surface offers several advantages for initial implementation of CNFETs within manufacturing facilities. For example, this technique has a low barrier for integration.

In embodiments, uniform CNT deposition is demonstrated across 200 mm substrates using existing equipment already being used for silicon-CMOS fabrication within these facilities), and solution-based CNTs can be synthesized in large quantities for high-volume production while meeting CNT material-level requirements for realizing digital VLSI circuits (semiconducting CNT purity ≥99.99%).

It has been recognized that there lacks a fundamental understanding of incubation methods and critical questions remain concerning manufacturability, compatibility, and the resulting CNFET performance that can be achieved via incubation method.

To address these challenges, described herein are the results of the first in-depth characterization of CNT deposition through incubation. Also described are the use of these results to elucidate the mechanisms driving CNT deposition.

Leveraging this insight, deposition techniques (and in embodiments, significantly improved deposition techniques compared with prior art techniques) achieving both increased throughput as well as reduced cost (critical factors in realizing a feasible future commercial CNFET technology) have been developed and experimentally demonstrates. This enables the first introduction of CNFETs fabricated within multiple industry manufacturing facilities. In one embodiment, CNFETs were fabricated in a commercial silicon manufacturing facility (Analog Devices Inc., a facility with >43,000 different products in production) as well as a high-volume manufacturing semiconductor foundry (SkyWater Technology, a U.S.-based semiconductor foundry with >12,000 wafer starts per month capacity).

Taken together, the concepts, systems and techniques described herein make at least the following contributions: (a) the first in-depth characterization of CNT deposition through incubation, providing fundamental insights into the mechanisms driving CNT deposition and factors that influence deposition rate and CNT density achieved; and (b) application of this understanding to develop and experimentally demonstrate deposition techniques that achieve a >1,100× speed-up in processing time compared with processing times achieved with prior art techniques (from >48 hours to 150 seconds) while simultaneously reducing the cost of the CNT solution.

Described herein are CNFETs fabricated within multiple industrial manufacturing facilities, enabled by implementing the advances described above. These CNFETs may be fabricated using the same equipment currently being used to fabricate silicon product wafers, explicitly demonstrating that CNFET fabrication is silicon-CMOS compatible. This contribution is also enabled by the use of highly-purified semiconducting CNT solutions that meet the stringent chemical and particulate contamination requirements for inclusion into these facilities.

Also described is the first experimental demonstration of uniform and reproducible CNFET fabrication across industry-standard wafers (e.g. wafers having a diameter in the range of about 200 mm to about 450 mm and above), yielding 14,400/14,400 CNFETs distributed across multiple wafers and the entire substrate (e.g., across an entire 200 mm or 300 mm substrate without removing any outliers). In one embodiment, the CNFET technology is implemented at a ˜130 nm technology node.

Also described is analysis illustrating that the incubation method of CNT deposition is sufficient for realizing a future CNFET technology that is competitive with silicon FETs at comparable technology nodes. This analysis uses industry-practice electronic design automation (EDA) tools and design flows for quantifying total energy consumption and clock frequency of VLSI CNFET circuits (a commercial-grade processor core).

This work demonstrates the feasibility of commercial CNFET manufacturing given CNT processing capabilities today, while simultaneously providing a path for realizing CNFET energy-efficiency benefits.

Accordingly, described herein are concepts, systems, circuits, devices, structures and methods for depositing carbon nanotubes (CNTs) uniformly over a substrate. The described concepts, systems, circuits, devices, structures and methods meet at least several requirements; namely, the systems, circuits, devices, structures are: (1) manufacturable; (2) silicon-CMOS compatible; and (3) provide a path for realizing energy efficiency benefits utilizing silicon. In embodiments, described is an illustrative CNT solution-based deposition technique that addresses all of these requirements.

Also described is a method for providing carbon nanotube field effect transistors (CNFETs) using uniform and reproducible fabrication techniques. Furthermore, such techniques are suitable for use across industry-standard wafers sizes, and importantly may use the same equipment currently being used to fabricate silicon product wafers.

Also described are CNFETs fabricated within commercial silicon manufacturing facilities and having wafer-scale uniformity and reproducibility across multiple 200 mm wafers.

By elucidating fundamental mechanisms driving CNT deposition, processes resulting in significant improvements in the time required for the CNT deposition process while simultaneously reducing cost may be achieved.

Leveraging these advancements, described are the first introduction of CNFETs within multiple industry manufacturing facilities: both a commercial silicon fabrication facility as well as a high-volume commercial foundry. This includes the first demonstration of uniform and reproducible CNFET fabrication across industry-standard 200 mm wafers, and importantly, uses the same equipment currently being used to fabricate silicon product wafers. This is a major milestone for CNFET technologies and paves the way for continued transitioning of CNFETs into industry.

By elucidating fundamental mechanisms driving CNT deposition, processes resulting in significant improvements in reducing the time required for the CNT deposition process >1,100× while simultaneously reducing cost. Leveraging these advancements, described are the first introduction of CNFETs within multiple industry manufacturing facilities including both a commercial silicon fabrication facility as well as a high-volume commercial foundry. This includes the first demonstration of uniform and reproducible CNFET fabrication across industry-standard wafers, and importantly, uses the same equipment currently being used to fabricate silicon product wafers. This is a major milestone for CNFET technologies and paves the way for continued transitioning of CNFETs into industry.

Thus, CNFETs may be fabricated within commercial silicon manufacturing facilities, demonstrating wafer-scale uniformity and reproducibility across multiple wafers (e.g. multiple 200 mm, 300 mm or 450 mm diameter wafers).

By understanding the mechanisms driving CNT incubation, improved processes are developed that increase throughput and CNT density. Furthermore, the techniques described herein illustrate that the described CNT deposition techniques meet the requirements for realizing a manufacturable, silicon-CMOS compatible, and high-performance CNFET.

In accordance with a further aspect of the concepts described herein, a wafer-scale CNFET performance that meets the requirements for realizing CNFET digital logic is provided.

### BRIEF DESCRIPTION OF THE DRAWINGS

The manner and process of making and using the disclosed embodiments may be appreciated by reference to the drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIGS. 1A-1E are a series of diagrams which illustrate characterization of an incubation method for CNT deposition.

FIG. 1A is a diagram which illustrates methodology for characterizing the dependence of “linear CNT density” (i.e., the number of CNTs that cross a linear micron) as a function of time and CNT solution concentration.

FIG. 1B is a plot which Illustrates experimentally measured CNT linear densities as a function of concentration and incubation time.

FIG. 1C is a diagram which illustrates a carbon nanotube field-effect transistor (CNFET) having a bottom gate geometry.

FIG. 1D is a plot which illustrates equilibrium linear CNT density as a function of CNT concentration (Langmuir isotherm) for the CNT incubation method.

FIG. 1E is a plot which illustrates strength of CNT-substrate binding. Substrates are incubated for 30 minutes in a CNT solution of 1 μg/mL.

FIGS. 2A-2E are a series of diagrams which illustrates CNFET fabrication.

FIG. 2F is flow diagram illustrating a VLSI design and analysis flow for quantifying an energy-delay product (EDP) of a commercial-grade processor designed with CNFETs across a range of CNT densities.

FIGS. 2G-2I are a series of plots illustrating CNT density impact on CNFET circuit energy efficiency.

FIG. 2G is a plot of energy vs. clock frequency Pareto-optimal curves extracted using the simulation framework described in FIG. 2F for a range of CNT densities.

FIG. 2H is a plot of EDP vs CNT density, extracted from FIG. 2G.

FIG. 2I is a colormap plot which illustrates the Effect of CNT rotational alignment on drive current.

FIG. 3A is an Illustration of a dry-cycling methodology.

FIG. 3B is a plot of a Linear CNT Density vs. Incubation Time

FIG. 3C is an Illustration of the artificial concentration through evaporation (ACE) methodology.

FIG. 3D is a plot of a comparison of CNT deposition rate for baseline incubation (a single cycle deposition) vs deposition rate achieved through dry-cycling incubation at the same CNT concentration (1 μg/mL).

FIGS. 4A-4G are a series of diagrams illustrating first integration of CNFETs within a commercial silicon foundry.

FIG. 4A is an image of a commercial wet processing station within the silicon commercial foundry for automatically performing all CNT incubation process steps (CNT incubation, optional dry-cycling/ACE, solvent rinses, and nitrogen dry).

FIG. 4B is an image of a 200 mm CNFET wafer fabricated within the commercial silicon foundry.

FIG. 4C is an image of a single die from the 200 mm CNFET wafer.

FIG. 4D is a scanning electron microscopy (SEM) image of a CNFET, fabricated at a ˜130 nm technology node. Individual CNTs are not visible through the channel due to the metal gate beneath the CNTs.

FIG. 4E is a SEM cross-sectional view of two series CNFETs fabricated at a ˜130 nm technology node.

FIG. 4F are SEM images of uniform CNT deposition taken across multiple 200 mm substrates, demonstrating uniform and reproducible CNT deposition. Three columns are images taken at 3 different locations across the 200 mm wafer (see FIGS. 13A, 13B for further SEM characterization of CNT deposition across 200 mm substrates.

FIGS. 4G-4I introduce the CNTs within these commercial manufacturing facilities, substantial efforts were made to meet the strict chemical and particulate contamination limits required of any material within these facilities.

FIG. 4G is an image illustrating that front-side CNTs are not impacted by front-side sonicating sprays, demonstrating that once adhered to the wafer, the CNTs are not unintentionally removed during subsequent processing steps.

FIG. 4H is an image illustrating that developed backside wafer cleans can successfully remove all CNTs on the backside of wafers, avoiding backside contact contamination during wafer handling.

FIG. 4I is a matrix illustrating a 70-element analysis of potential contaminants introduced onto wafers during CNT incubation, measured through laser-ablation ICP-MS. All 70 elements listed had contamination below the detectable limits.

FIGS. 5A-5C are a series of figures illustrating electrical characterization of CNFETs fabricated across 200 mm substrates within the commercial silicon foundry.

FIG. 5A is a wafer map illustrating the die locations that are measured, showing wafer-scalable processing.

FIG. 5B are plots of typical I_{D}-V_{DS} and I_{D}-V_{GS} characteristics for the CNFETs.

FIG. 5C is a series of plots illustrating electrical characterization of CNFETs measured across 200 mm substrates and across three different wafers.

FIGS. 6A, 6B illustrate electrical characterization of CNFETs fabricated through dry-cycling and ACE. All CNFETs are fabricated within the commercial silicon foundry, across 200 mm substrates. Four wafers are fabricated, undergoing either a single, three, five, or ten dry-cycling deposition cycles.

FIG. 6A is a plot which illustrates an average drive current for each wafer, demonstrating the expected approximately linear relationship between the number of deposition cycles and CNFET drive current.

FIG. 6B is a plot which illustrates that an average inverse sub-threshold slope is approximately constant across all of the wafers, illustrating similar gate control regardless of the number of dry-cycling depositions. Sample size=800 CNFETs.

FIGS. 7A-7E are a series of plots which illustrate Kinetic analysis of CNT deposition.

FIG. 7A is a plot of experimental data used in the kinetic analysis (3 different concentrations).

FIG. 7B is a series of plots which illustrate a pseudo-first order analysis. Experimental data from each concentration is linearized according to equation 1 and fit with the least squares method.

FIG. 7C is a series of plots which illustrate a pseudo-second order analysis. Experimental data is linearized according to equation 2 and fit with the least squares method.

FIG. 7D is a series of plots which illustrate a comparison of pseudo-first and pseudo-second order fits. The experimental data is shown along with the computed pseudo-first and pseudo-second order models.

FIG. 7E is a table of computed model parameters.

FIGS. 8A-8D illustrate a framework for analyzing impact of CNT incubation on CNFET drive current.

FIG. 8A illustrates CNFET initialization.

FIG. 8B illustrates CNTs at a given length are randomly placed and assigned a rotation.

FIG. 8C Illustrates a trial with 50 CNTs/μm.

FIG. 8D is a diagram which Illustrates the resulting resistor network for the CNFET formed in FIG. 8B.

FIG. 8E is a plot which illustrates definitions of “physical” channel length versus “effective” channel length.

FIGS. 9A-9E are a series of plots which illustrate variability and functional yield versus geometry.

FIG. 9A illustrates simulated device variability (characterized as the coefficient of variation, the ratio of standard deviation to the mean) for devices formed with aligned CNTs as a function of channel width (W_{channel}) and channel length (L_{channel}) for several linear CNT densities (28, 85, and 143 CNTs/μm).

FIG. 9B illustrates simulated device variability (coefficient of variation) for devices formed with unaligned CNTs as a function of W_{channel} and L_{channel} for several linear CNT densities.

FIG. 9C illustrates Relative variability measured as coefficient of variation for the unaligned case normalized to the coefficient of variation for the aligned case.

FIG. 9D illustrates simulated functional yield from devices made from aligned CNTs as a function of W_{channel} and L_{channel} for several linear CNT densities.

FIG. 9E illustrates simulated functional yield from devices made from unaligned CNTs as a function of W_{channel} and L_{channel} for several linear CNT densities. Functional yield is defined as a CNFET that has at least a single CNT bridging between the source and drain.

FIGS. 10A-10C are a series of diagrams which show the Effect of CNT length on drive current.

FIG. 10A illustrates simulated drain current as a function of L_{channel} and linear CNT density for aligned CNTs given different CNT lengths (from 600 nm to 1600 nm).

FIG. 10B illustrates simulated drive current as a function of L_{channel} and linear CNT density for unaligned CNTs given different CNT lengths.

FIG. 10C illustrates a ratio of current with aligned CNTs to the current with unaligned CNTs (I_{D,aligned}/I_{D,unaligned}) as a function of L_{channel} and linear CNT density.

FIGS. 11A-11C are a series of diagrams which illustrate the effect of degree of CNT alignment on drive current.

FIG. 11A illustrates simulated drive current as a function of channel length (L_{channel}) and linear CNT density for varying degrees of CNT rotational mis-alignment. The degree of alignment decreases from top to bottom. Colorbar in arbitrary units. All simulated CNFETs have channel width of 2 μm.

FIG. 11B illustrates simulated normalized drive current (I_{D,rot}/I_{D,aligned}) as a function of L_{channel} and linear CNT density for varying degrees of CNT rotational mis-alignment.

FIG. 11C shows the average I_{D,rot}/I_{D,aligned} (over all L_{channel} and CNT densities) as a function of degree of CNT rotation mis-alignment.

FIG. 12A is an image of CNFETs fabricated within a commercial silicon manufacturing facility. FIG. 12A is a scanning electron microscopy (SEM) image of CNT incubation performed over a local bottom gate (Tungsten metal damascene process) and high-k gate dielectric.

FIG. 12B is a plot of overlaid I_{D}-V_{GS} measurements of 150 typical CNFETs, achieving on/off ratio of ˜10⁴.

FIGS. 13A, 13B are SEM images of uniform 200 mm wafer-scale CNT deposition across multiple wafers. Scale bar for all images in a row are shown in the left column. FIGS. 13A, 13B show typical images of CNT incubation from the silicon manufacturing foundry. Images are taken across multiple 200 mm wafers illustrating uniformity and reproducibility.

FIG. 14 is a series of images which together illustrate the process of measuring linear CNT density: the number of CNTs per linear micron. FIG. 14 is an Illustration of the linear density measurement process. After CNT deposition, eight images are taken over the surface of the substrate using helium ion microscopy. For each image, the linear CNT density is counted by drawing a line through the image and counting the number of crossing CNTs. Since the field of view is known (in this case 500 nm) the number of CNTs crossing a linear micron can be calculated. This is repeated three times for each image.

### DETAILED DESCRIPTION OF EMBODIMENTS

Before proceeding with a discussion of concepts, systems, circuits, devices, structures and techniques for depositing carbon nanotubes (CNTs) uniformly over a substrate, it should be appreciated that to promote clarity in the description of the broad concepts sought to be protected herein, some example use cases are discussed below. Such use case are not intended to be and should not be construed as limiting. Rather, any specific examples provided herein below are merely instructive of the broad concepts sought to eb protected.

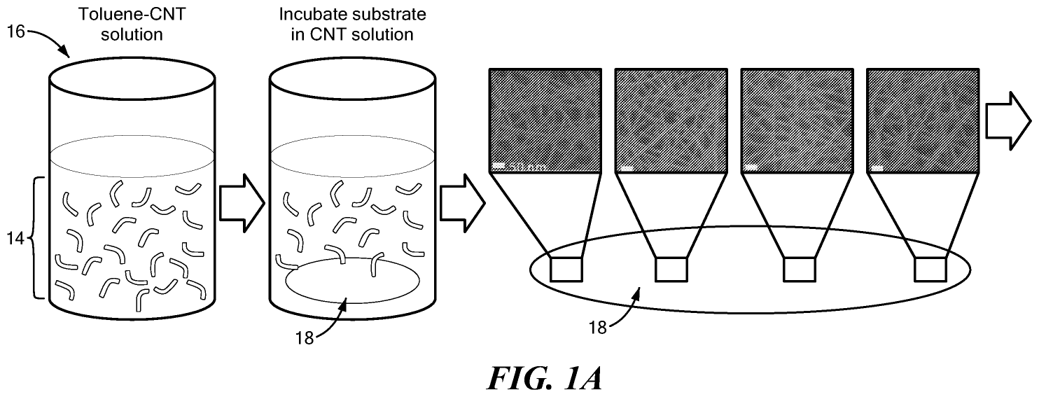

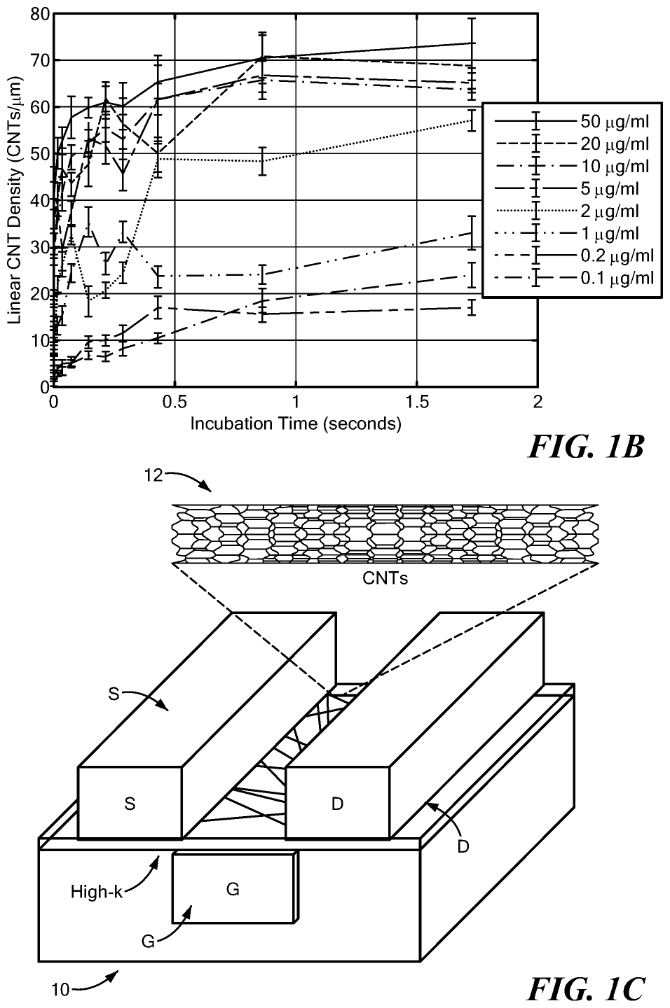

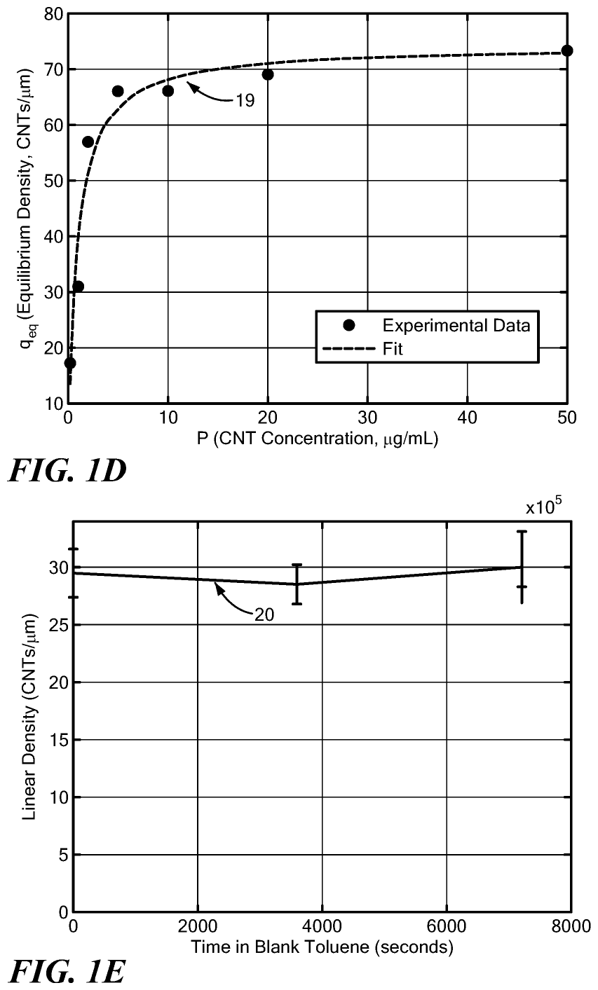

With reference now to FIGS. 1A-1E, one leading candidate material for realizing beyond-silicon FETs are carbon nanotubes (CNTs). To realize a carbon nanotube field-effect transistor (CNFET) 10 having source (S), drain (D), and gate (G) regions (as illustrated in FIG. 1C), multiple CNTs 12 in parallel comprise the channel of the FET. In embodiments, the source, drain, and gate regions may be lithographically-defined.

Owing to the ultra-thin body of a CNT (˜1.2 nm diameter, forming a one-dimensional semiconductor) with its simultaneously high carrier transport, digital very-large-scale-integrated (VLSI) circuits fabricated from CNFETs are projected to achieve an order of magnitude improvement in energy-delay product (EDP, a metric of energy efficiency) as compared with the EDP of silicon-based FETs. Moreover, CNFETs are a rapidly maturing technology as complete CNFET CMOS digital systems (such as a 16-bit RISC-V microprocessor) as well highly-scaled and high-performance CNFETs have been demonstrated.

In FIGS. 1A-1E, characterization of an incubation method for CNT deposition is described.

FIG. 1A illustrates a methodology for characterizing the dependence of “linear CNT density” (i.e., the number of CNTs that cross a linear micron: as a function of time and CNT solution concentration). In embodiments, a substrate 14 is submerged in a toluene-based CNT suspension 16 at varying concentrations for varying time. After the substrate is removed and dried, helium ion microscopy maybe used to extract the linear CNT density (region 18).

FIG. 1B is a plot which Illustrates the experimentally measured CNT linear densities as a function of concentration and incubation time. As can be seen from FIG. 1B, the CNT deposition rate is rapid at the beginning of incubation and plateaus at long incubation times. Each data point is the average of 24 measurements, error bars show the 97.5% confidence interval.

FIG. 1C is a schematic diagram of a CNFET having a bottom gate geometry. As noted above, multiple CNTs 12 in parallel form the channel of the FET.

FIG. 1D is a plot which illustrates equilibrium linear CNT density as a function of CNT concentration (Langmuir isotherm) for the CNT incubation method (see curve 18). The “equilibrium” linear CNT density (taken as the linear CNT density after 48 hours of incubation) is strongly dependent on the concentration of the CNT solution used in the incubation process, characteristic of an adsorption process.

FIG. 1E is a plot which illustrates strength of CNT-substrate binding. In one illustrative embodiment, substrates are incubated for 30 minutes in a CNT solution of 1 μg/mL. After being removed from the CNT solution and dried, the substrates are re-incubated in blank toluene (no CNTs) for varying amounts of time. The CNT linear density from the samples that incubated in blank toluene shows no significant difference from the control samples (no toluene incubation) for up to two hours. This illustrates that CNTs dried on the substrate surface show no propensity to desorb back into solution for at least two hours.

FIGS. 1-1E show experiments characterizing the CNT incubation process (we refer to this CNT incubation process as “baseline incubation”). Initially, the CNT deposition dependency may be investigated on basic process parameters: the concentration of the CNT suspension in toluene (from 0.1 μg/mL to 50 μg/mL), and the CNT incubation time (ranging from 1 second to 48 hours). For each condition, the resulting CNT density is extracted at 24 locations across each sample. The data gathered from this set of experiments is presented in FIG. 1B and illustrates several important points.

First, CNT deposition shows a trend that is characteristic of many adsorption processes: namely, a rapid initial deposition which then saturates to a self-limiting CNT density after long incubation times (we refer to this saturation as the “equilibrium” linear CNT density). In understanding that this process is adsorptive in nature, we can gain insight into the underlying mechanism driving CNT deposition by examining the process through the lens of Langmuir adsorption theory.

While the physics in the described system deviates from this ideal case, Langmuir theory is commonly used to gain a basic intuition about solution-based nanomaterial deposition similar to this one. In Langmuir theory, both adsorption and desorption are reversible counter-acting processes that occur simultaneously. The number of CNTs that are bound to the surface of a substrate at any given time is a function of the relative rates of the adsorptive and desorptive sub-processes. At the beginning of the incubation, there are no CNTs bound to the substrate so the rate of adsorption is infinitely higher than that of desorption (which is zero). This results in the rapid initial deposition rate seen for all concentrations in FIG. 1B.

As more CNTs are deposited on the surface, the rates of desorption and adsorption gradually balance, and the number of CNTs bound to the substrate plateaus to a terminal equilibrium value that is dependent on the concentration of CNTs in the solution. While this plateau limits the CNT density that can be achieved (even at long incubation times), the self-limiting nature ensures that the deposition process does not result in arbitrarily thick films of CNTs (which can occur with other CNT deposition techniques such as dropcasting, leading to degradation of FET electrostatic control).

FIG. 1D shows that the equilibrium linear density (linear CNT density after 48 hours of incubation) is strongly dependent on CNT solution concentration. Increasing concentration is a simple method for increasing CNT density, however provides diminishing returns at higher CNT concentrations.

The competing processes of adsorption and desorption during incubation raise additional questions concerning how strongly CNTs adhere to the wafer after incubation. FIG. 1E shows additional experiments that explicitly investigate the CNT-substrate binding. After performing the CNT incubation process described above (CNT incubation followed by solvent spray and nitrogen dry), the substrates then go through another round of incubation in blank toluene (toluene with no CNTs) for increasing periods of time. FIG. 1E shows that there is no significant difference in linear CNT density between control samples (not exposed to blank toluene after initial incubation) and the samples that were submerged in blank toluene for up to two hours. This suggests that after the substrate is removed from the CNT solution and dried, the CNTs remain adsorbed tightly to the substrate with no measurable propensity to desorb (for at least up to two hours). Further details of the kinetics, characterization, and nature of the deposition process are described herein. One outcome from FIGS. 1A-1E 1 is that CNT incubation can realize high CNT densities >75 CNTs/μm.

While promising, this is below the projected optimal CNT density of ˜200 aligned CNTs/μm from prior theoretical works.

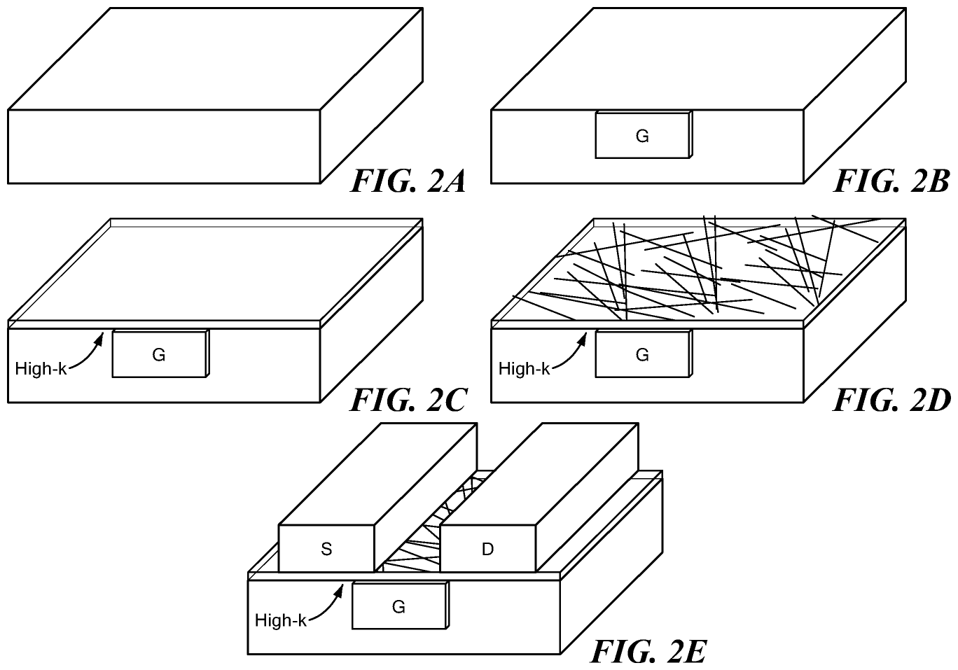

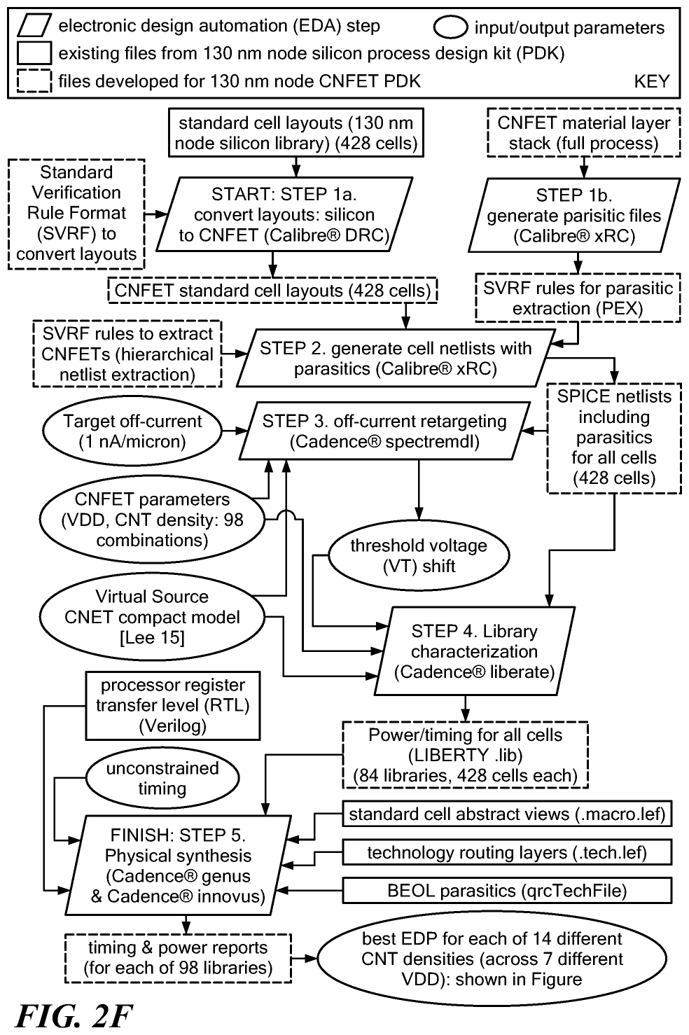

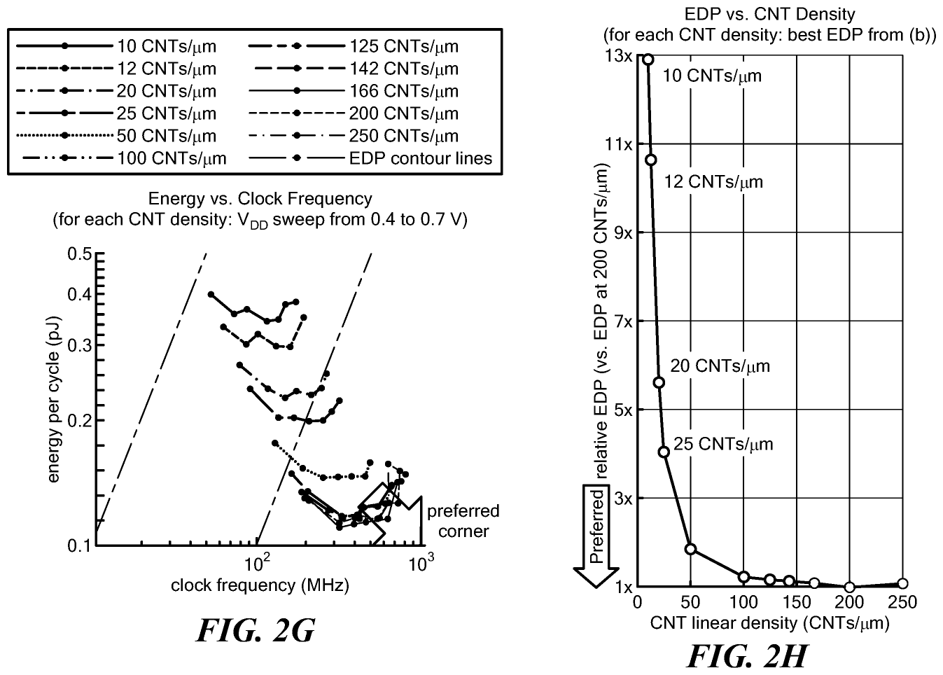

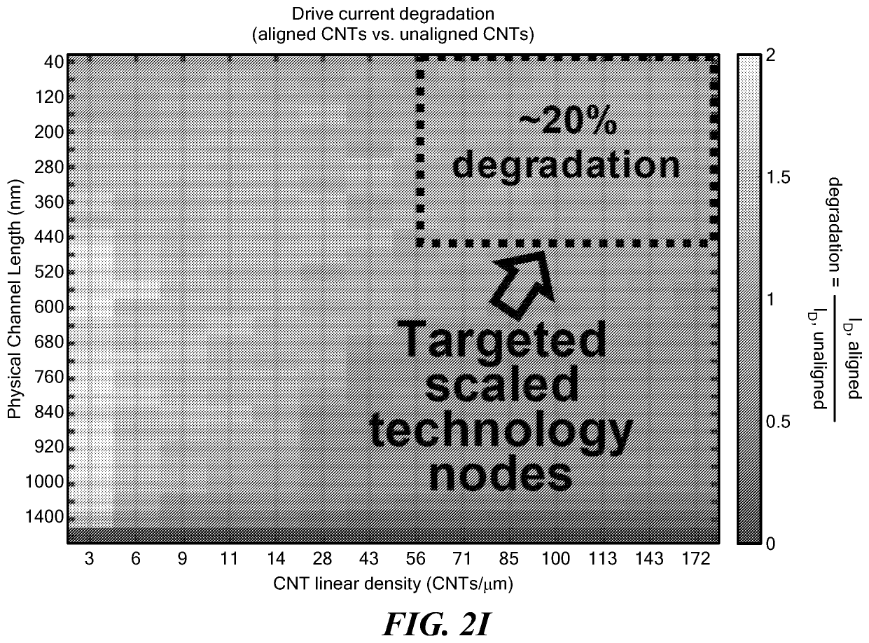

Referring now to FIGS. 2A-2E, process steps for a CNFET include local bottom gate definition (FIG. 2B), high-k gate dielectric deposition (FIG. 2C), CNT deposition through incubation (FIG. 2D), metal source and drain contact definition, and removing of extraneous CNTs outside the channel region of the CNFETs (FIG. 2E). In embodiments, the gate may be defined through a Tungsten damascene process. In embodiments, the high-k gate dielectric deposition may be accomplished through atomic layer deposition (ALD).

To analyze the projected EDP cost associated with lower and unaligned CNT densities, we develop industry-practice CNFET process design kits (PDKs) to design and analyze commercial VLSI CNFET processor cores leveraging calibrated compact models across different CNT densities (see FIG. 2F).

FIG. 2F is flow diagram illustrating a VLSI design and analysis flow for quantifying an energy-delay product (EDP) of a commercial-grade processor designed with CNFETs across a range of CNT densities. The simulation framework quantifies the total energy consumption and clock frequency of VLSI commercial-grade processors designed using CNFETs, using experimentally-calibrated CNFET compact models, commercial grade process design kits (PDKs), and industry-standard tool flows.

In FIGS. 2G-2I, shown are analysis results of the impact of varying CNT density (though still assuming aligned CNTs) on overall VLSI CNFET circuit energy efficiency (quantified by EDP). While an optimal CNT density of about 200 (denoted ˜200) CNTs/μm (to optimize CNFET circuit EDP) is consistent with existing literature (from prior works, ˜200 CNTs/μm results in about 10 (denoted ˜10)×EDP benefit vs. silicon CMOS⁴), it has herein been demonstrated that relaxing the CNT density to about 75 (denoted ˜75) CNTs/μm only degrades EDP by about 1.5 (denoted ˜1.5)×(which would therefore still result in a significant about 6.5 (denoted ˜6.5)×EDP benefit vs. silicon CMOS). In fact, reducing CNT density to even 25 CNTs/μm can still enable a substantial about 2.5 (denoted ˜2.5)×benefit in EDP vs. silicon CMOS (for perspective, scaling from a state-of-the-art 7 nm node to a projected 5 nm silicon-based technology provides about 1.4 (denoted ˜1.4)×EDP benefit³⁴). Details of the VLSI design methodology to analyze CNFET circuit EDP as a function of CNT density is described herein.

FIG. 2G is a plot of energy vs. clock frequency Pareto-optimal curves extracted using the simulation framework described in FIG. 2F for a range of CNT densities. The absolute values of the clock frequency and energy-per-cycle are determined by the specific design of the commercial-grade processor being analyzed. The Pareto-optimal curve for each CNT density is generated by sweeping V_{DD} from 0.4V to 0.7V, and re-optimizing threshold voltage for each V_{DD}.

FIG. 2H is a plot of EDP vs CNT density, extracted from FIG. 2G. The EDP shown for each CNT density is the best EDP extracted from the Pareto-optimal curves in FIG. 2G. Importantly, while low CNT densities (<50 CNTs/μm) result in substantial increasing (i.e., degraded) EDP, the EDP vs. CNT density relationship is relatively flat for CNT densities >50 CNTs/μm. Therefore, a reduced amount of (and ideally, minimal) EDP degradation is associated with relaxing CNT densities to below the optimal ˜200 CNTs/μm. For instance, while 200 CNTs/μm provides the expected optimal EDP (from prior works, ˜200 CNTs/μm results in ˜10×EDP benefit vs. silicon CMOS), relaxing the CNT density to ˜75 CNTs/μm only degrades EDP by ˜1.5× (which would therefore still result in ˜6.5×EDP benefit vs. silicon CMOS). In fact, reducing CNT density to even just 25 CNTs/μm can still enable a substantial ˜2.5× benefit in EDP vs. silicon CMOS. For perspective, scaling from a state-of-the-art 7 nm node to a projected 5 nm silicon-based technology provides ˜30% EDP benefit.

While the analysis above reveals the trade-off between CNT density and potential CNFET EDP benefits, this analysis assumes that the CNTs are aligned. However, CNT incubation does not provide control over CNT orientation, resulting in unaligned CNTs.

FIG. 2I simulates the impact of CNT alignment on CNFET drive current (simulation details as described herein). FIG. 2I is a colormap plot which illustrates the Effect of CNT rotational alignment on drive current. The colormap illustrates the degradation in drive current associated with unaligned CNTs versus aligned CNTs, given the same CNT linear density. Values greater than 1 correspond to CNFETs with unaligned CNTs having lower drive current than CNFETs with aligned CNTs; values below 1 correspond to CNFETs with unaligned CNTs having higher drive current than CNFETs with aligned CNTs. While at larger CNT channel lengths and lower CNT densities the drive current degradation approaches 2×, for a targeted future CNFET digital logic technology at a scaled node (i.e., scaled physical channel lengths) and high CNT density (>40 CNTs/um), the total degradation in drive current due to unaligned CNTs is <20% (the region of the colormap associated with a targeted future scaled technology node, including what this work experimentally demonstrates within a silicon commercial foundry, is outlined in FIG. 2I. A “targeted scaled technology node” refers to typical targets for a future CNFET technology, which would require scaled channel lengths as well as sufficient CNT density based on FIG. 2H.

As expected, unaligned CNTs degrade CNFET drive current versus aligned CNTs. This degradation in drive current is due to both an increase in effective channel length as well as a decrease in the probability that a CNT spans the entire channel when the CNT is not aligned. However, if the CNT length is significantly larger than the channel length (a realistic assumption for commercial scaled technology nodes), the degradation in drive current is ≤20% (a full analysis and comparison between aligned vs. unaligned CNTs is provided herein below).

While improving CNT density to 200 CNTs/μm provides a path for further EDP benefits, FIGS. 2A-2I shows that the incubation method of CNT deposition can still enable a CNFET technology which exceeds the performance of silicon CMOS given processing capabilities that exist today (we show that CNT density as well as CNT mis-alignment is not a limiting factor for achieving energy-efficiency benefits compared to silicon CMOS).

While the analysis in FIGS. 2G-2I shows that CNT incubation can realize a CNFET technology that exceeds the performance of silicon CMOS, achieving high CNT densities presents major feasibility challenges for industry integration. Reaching CNT densities of >75 CNTs/μm requires both very long CNT incubations (on the order of days, severely limiting throughput) as well as very high CNT solution concentrations. Large quantities of purified CNTs at high concentration significantly increases cost. In addition, concentration affects the lifetime of the CNT solution; we observe that at higher CNT concentrations, the CNTs suspended in solution aggregate a faster rate than the low concentration solutions.

To address these remaining obstacles, insights gained from FIGS. 1A-1E may be leveraged to modify the CNT incubation process to rapidly increase CNT linear density while using dramatically lower CNT concentrations.

From the baseline CNT incubation characterization (FIGS. 1A-1E), it is noted that the Langmuir model describes CNT deposition rate as a function of the relative adsorption and desorption rates. Therefore, increasing CNT deposition rate can be realized by either increasing the adsorption rate or by decreasing desorption rate.

To decrease desorption rate, insight from FIG. 1E may be leveraged to show that the desorption rate of CNTs once they have dried on the substrate is approximately zero (i.e., the CNTs are effectively “frozen” in place).

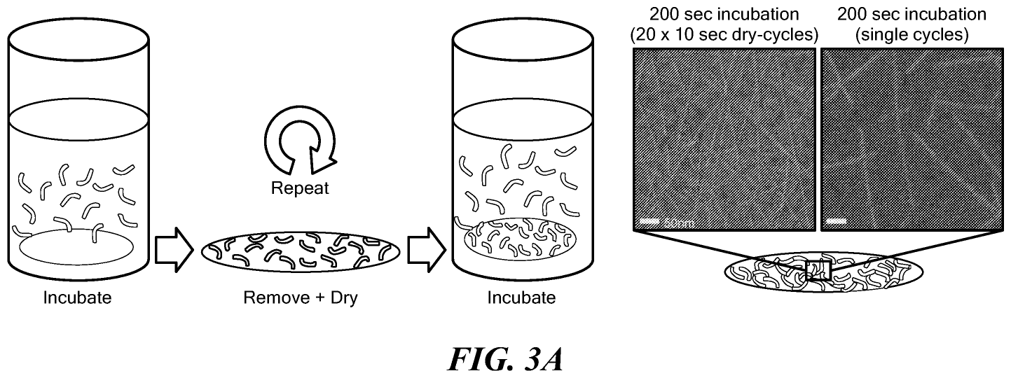

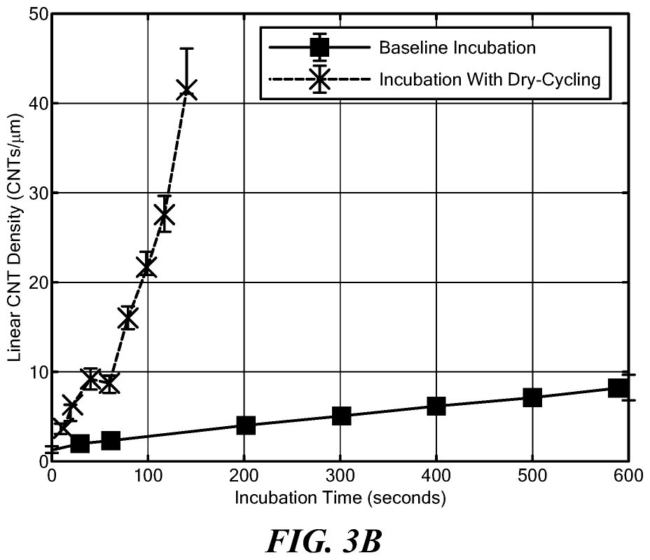

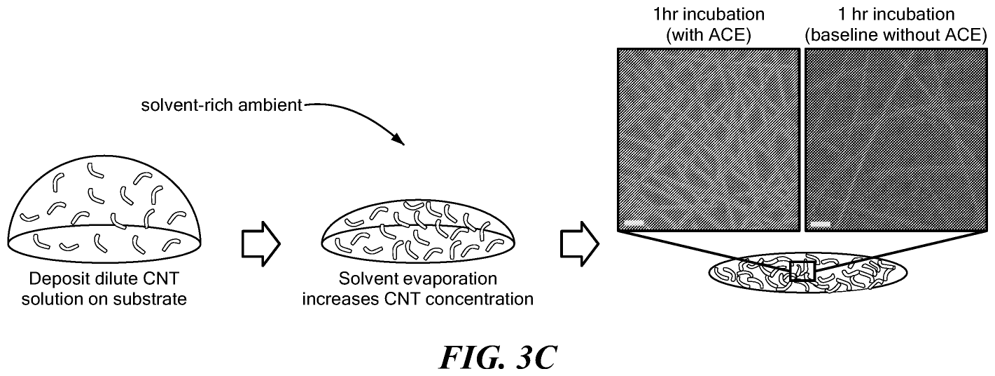

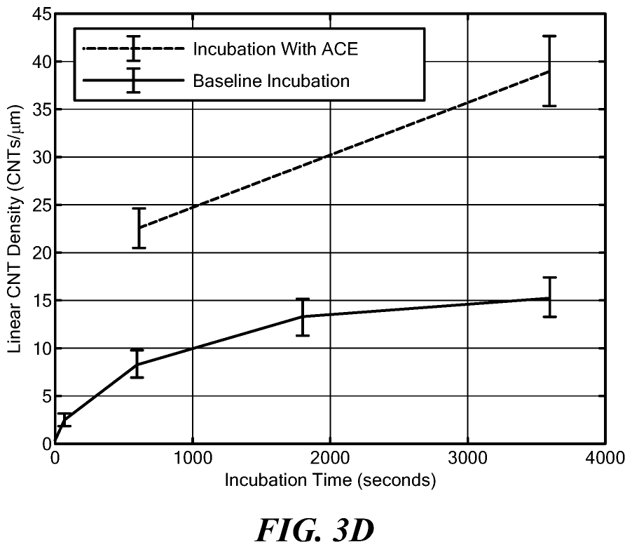

FIGS. 3A-3D are a series of figures which illustrate methodologies for improving CNT deposition through incubation.

FIGS. 3A-3B illustrate a CNT incubation methodology, “dry-cycling” incubation, which leverages the drying process to reduce desorption rate and tilt the balance in favor of faster deposition. To perform dry-cycling incubation, the substrates (prepared as described) are submerged into CNT solution and incubate for a period of time in the range of 1 second to 45 seconds and in some embodiments for a period of time in the range of about 10 seconds (leveraging the fast, linear deposition regime). The substrates are then removed from the solution, rinsed with a solvent spray, and dried with nitrogen. This process (a “single-cycle” incubation) is then repeated multiple times.

The resulting CNT linear density is shown in FIG. 3B, alongside control samples that were incubated for the same total amount of time but without the intermittent drying. The intermittent drying results in increases in CNT deposition (and in some embodiments, dramatic increases in CNT deposition): ˜45 CNTs/μm after 150 seconds is ˜1.5× the maximum possible equilibrium density using the same CNT solution concentration of 1 μg/ml with a >1,100× reduction in incubation time (150 seconds total incubation time with dry-cycling versus a 48-hour constant single-cycle baseline incubation). As discussed below, electrical characterization further demonstrates that CNFET electrical performance is not impacted by the number of dry-cycling intervals.

In addition to decreasing desorption rate, an additional approach for increasing CNT deposition rate is to increase the rate of adsorption.

To accomplish this, and with reference to FIGS. 3C, 3D, another CNT incubation methodology (referred to as Artificial Concentration through Evaporation (ACE) was developed. In contrast to baseline incubation (whereby the substrate is left submerged within a tank of CNT solution), ACE is implemented by depositing small volumes of solution on the substrate surface in a controlled ambient. Over time, the solvent slowly evaporates from the CNT solution, artificially increasing the concentration of CNTs beyond the starting concentration. By artificially concentrating the CNTs on the wafer surface, the adsorption rate increases, resulting in increased CNT density for any starting CNT solution concentration (see FIGS. 1B-1D for dependency of CNT deposition on CNT solution concentration).

FIG. 1D shows that increasing CNT concentration leads to diminishing returns in equilibrium CNT density as the concentration increases. ACE enables benefits in equilibrium CNT density without increasing the CNT concentration (and therefore cost) of the stock CNT solution. Importantly, the solvent evaporation rate is critical for uniformity, as slipping during rapid droplet evaporation causes the “coffee ring effect” and results in non-uniform deposition across the substrate. In addition to slowing the evaporation rate, the solvent-rich ambient reduces the surface tension at the CNT solution-air interface, avoiding the “coffee ring effect.”

Additionally, complete drying disturbs the careful balance of adsorption and desorption, resulting in non-uniform thick-films of CNTs. To overcome this challenge, ACE is performed in a solvent-rich ambient, allowing for slow and controlled solvent evaporation (see Methods described hereinbelow). Before complete evaporation, the CNT solution is rinsed and the substrate is dried. FIG. 3G illustrates the benefit of ACE for CNT deposition: the linear CNT density increases >2.5× compared to baseline incubation controls given the same starting CNT solution concentration and processing time. Importantly, these techniques (dry-cycling, ACE) can be implemented in parallel to further improve deposition. Moreover, both dry-cycling and ACE do not require any equipment customization to realize substantial gains in throughput and final CNT density.

Referring now to FIGS. 3A-3C, described are methodologies for improving CNT deposition through incubation.

FIG. 3A Illustrates a dry-cycling methodology. The substrate is incubated for short times (˜10 sec), after which it is removed, dried, and returned to the CNT solution. This process is repeated for varying numbers of dry-cycles.

FIG. 3B shows a comparison of CNT deposition rate for baseline incubation (a single cycle deposition) vs deposition rate achieved through dry-cycling incubation at the same CNT concentration (1 μg/mL). Dry cycling achieved ˜45 CNTs/μm at 150 seconds of total incubation time, corresponding to a ˜1.5× improvement in linear density and >1,100× improvement in speed vs baseline incubation. Thus, FIG. 3B illustrates a comparison of linear CNT density achieved through incubation with ACE compared to baseline incubation. After one hour, ACE achieves ˜2.5× increase in density compared to baseline incubation using the same stock CNT concentration (1 μg/mL).

FIG. 3C is a series of views which provides an Illustration of the artificial concentration through evaporation (ACE) methodology. CNT solution at low concentration is deposited on the substrate. The solvent is allowed to incubate under a solvent-rich ambient. As the solvent evaporates, the remaining solution increases in CNT concentration. The solution can be either deposited on top of the wafer, or the wafer can be submerged within a tank of solution and immediately withdrawn, leaving a small volume of solution that completely covers the substrate surface.

FIG. 3D shows a comparison of linear CNT density achieved through incubation with ACE compared to baseline incubation. After one hour, ACE achieves ˜2.5× increase in density compared to baseline incubation using the same stock CNT concentration (1 μg/mL). Dry cycling achieved ˜45 CNTs/μm at 150 seconds of total incubation time, corresponding to a ˜1.5× improvement in linear density and >1,100× improvement in speed vs baseline incubation.

### Industry Integration

Leveraging these improved processes, we report the first integration of CNFETs within commercial silicon manufacturing facilities. Importantly, all CNFET fabrication is wafer-scale across entire 200 mm substrates and silicon-CMOS compatible (e.g., the CNFETs are fabricated using the same equipment used to fabricate silicon product wafers).

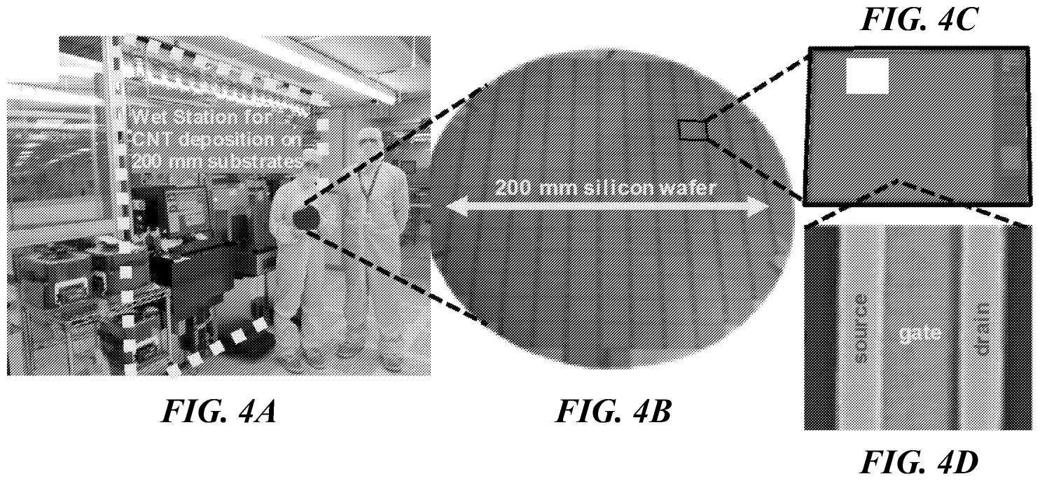

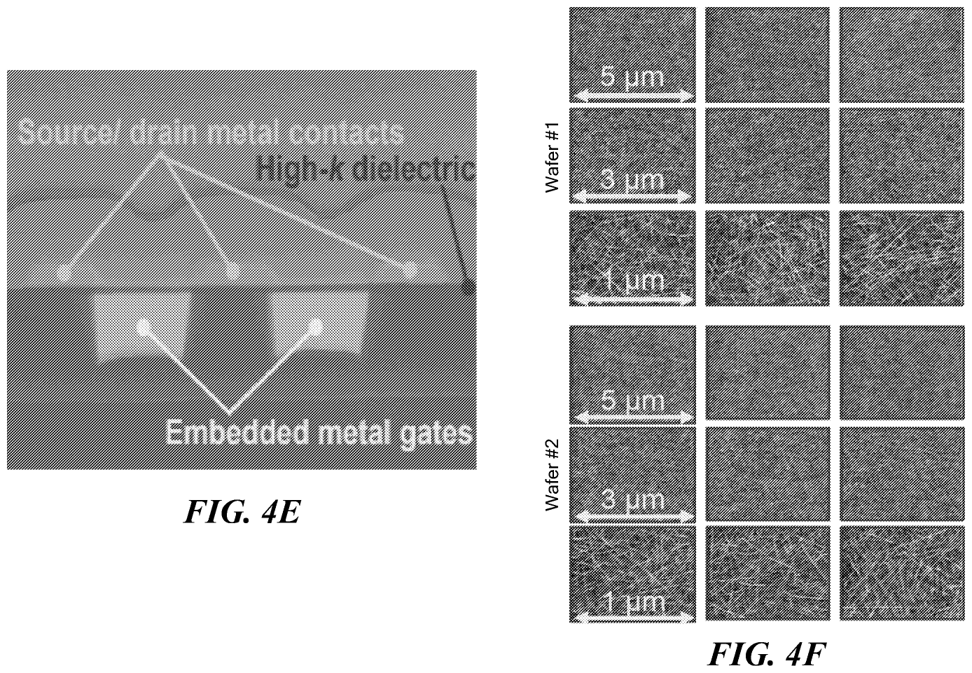

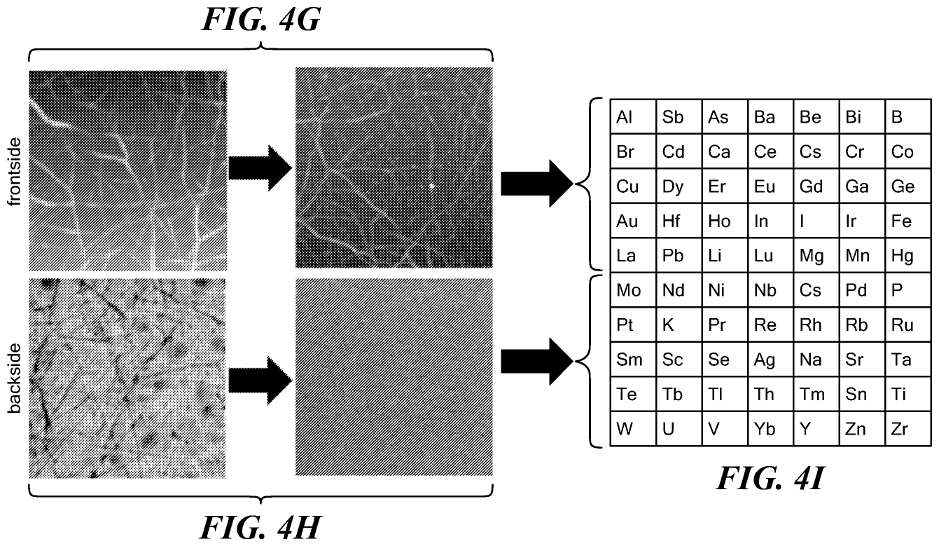

FIGS. 4A-4E highlight the silicon-CMOS compatibility of the CNT process. All of the CNFET fabrication is silicon-CMOS compatible as well as wafer-scale across entire 200 mm substrates. Such compatibility with existing silicon infrastructure is desirable when considering the feasibility of introducing new technologies to supplement existing silicon CMOS.

FIG. 4A shows the commercial wet processing station within the silicon commercial foundry that performs the CNT incubation. The wet processing station is programmed to automatically perform all process steps described above (CNT incubation, dry-cycling, ACE, solvent rinses and nitrogen dries, etc.). In order to introduce the CNT solution within these commercial manufacturing facilities, substantial efforts were made to ensure the CNTs themselves met the strict chemical and particulate contamination limits required of any material within these facilities. FIGS. 4G-4I shows some of these tests.

FIG. 4G shows that CNTs on the front-side of wafers are not impacted by sonicating clean-sprays, confirming that once adhered to the wafer, the CNTs will not be removed and contaminate downstream processing equipment (consistent with FIG. 1E). Similarly, to avoid backside contact contamination during wafer handling, FIG. 4H shows that developed backside cleans (alternating backside rinses in dilute HF and H₂O₂) remove all CNTs inadvertently deposited on the wafer backsides. Moreover,

FIG. 4I shows that our customized CNT solution preparation (see Methods) can successfully remove all chemical contaminants from the CNT solution. This is confirmed by performing inductively coupled plasma mass spectrometry (ICP-MS) analysis on the wafer surface immediately post-CNT deposition.

FIGS. 4A-4I, illustrate the first integration of CNFETs within a commercial silicon foundry. All of the CNFET fabrication is silicon-CMOS compatible as well as wafer-scale across entire 200 mm substrates. FIG. 4A shows a commercial wet processing station within the silicon commercial foundry for automatically performing all CNT incubation process steps (CNT incubation, optional dry-cycling/ACE, solvent rinses, and nitrogen dry).

FIG. 4B is an image of a 200 mm CNFET wafer fabricated within the commercial silicon foundry.

FIG. 4C is an image of a single die from the 200 mm CNFET wafer.

FIG. 4D is a scanning electron microscopy (SEM) image of a CNFET, fabricated at a ˜130 nm technology node. Individual CNTs are not visible through the channel due to the metal gate beneath the CNTs.

FIG. 4E is a cross-section SEM of two series CNFETs fabricated at a ˜130 nm technology node.

FIG. 4F is a series of SEM images of uniform CNT deposition taken across multiple substrates.

To introduce the CNTs within commercial manufacturing facilities (e.g. as shown in FIG. 4A), substantial efforts were made to meet the strict chemical and particulate contamination limits required of any material within these facilities. FIG. 4G shows that front-side CNTs are not impacted by front-side sonicating sprays, demonstrating that once adhered to the wafer, the CNTs are not unintentionally removed during subsequent processing steps. FIG. 4H shows that developed backside wafer cleans can successfully remove all CNTs on the backside of wafers, avoiding backside contact contamination during wafer handling. FIG. 4U is a table resultant from a 70-element analysis of potential contaminants introduced onto wafers during CNT incubation, measured through laser-ablation ICP-MS. All 70 elements listed had contamination below the detectable limits.

After wafer-scale CNT deposition, CNFETs are fabricated across the full substrate (e.g. the full 200 mm substrates). In embodiments, all CNFET fabrication may be performed within the foundry and may use the same equipment used to fabricate silicon product wafers. Scanning electron microscopy (SEM) images of uniform, wafer-scale CNT deposition as well as SEM cross-sectional views of CNFETs from the foundry are shown in FIGS. 4B-4F.

FIG. 4F is a series of SEM images of uniform CNT deposition taken across multiple 200 mm substrates, demonstrating uniform and reproducible CNT deposition. Three columns are images taken at 3 different locations across the 200 mm wafer. See the description herein below for further SEM characterization of CNT deposition across 200 mm substrates.

&&&In this example, the CNFETs are fabricated at a ˜130 nm technology node (corresponding to a contacted gate (poly) pitch, CPP, of ˜550 nm), and are fabricated with a high-k gate dielectric and metal gate stack. We introduce CNFETs at this mature technology node as it relaxes technology-level requirements while simultaneously providing benefits to silicon CMOS. In this example, all fabrication, ranging from CNT deposition to subsequent CNFET fabrication is low-temperature and back-end-of-line (BEOL) compatible. Therefore, these CNFETs can be fabricated directly in the BEOL over advanced-node silicon CMOS.

To characterize the CNFETs, 4,800 individual CNFETs were measured distributed across an entire 200 mm wafer (150 CNFETs distributed uniformly across each die). The measurements were repeated across 32 die across the wafer.

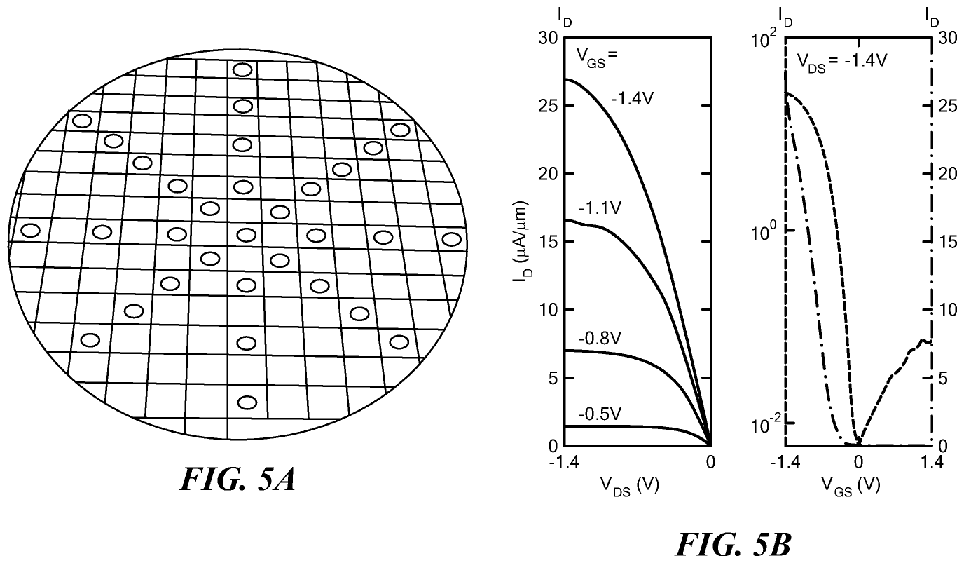

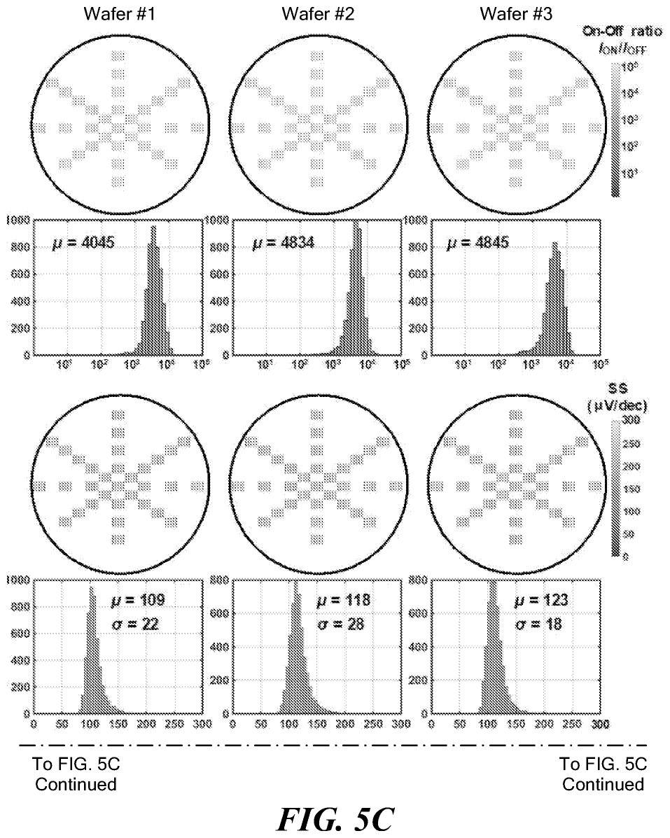

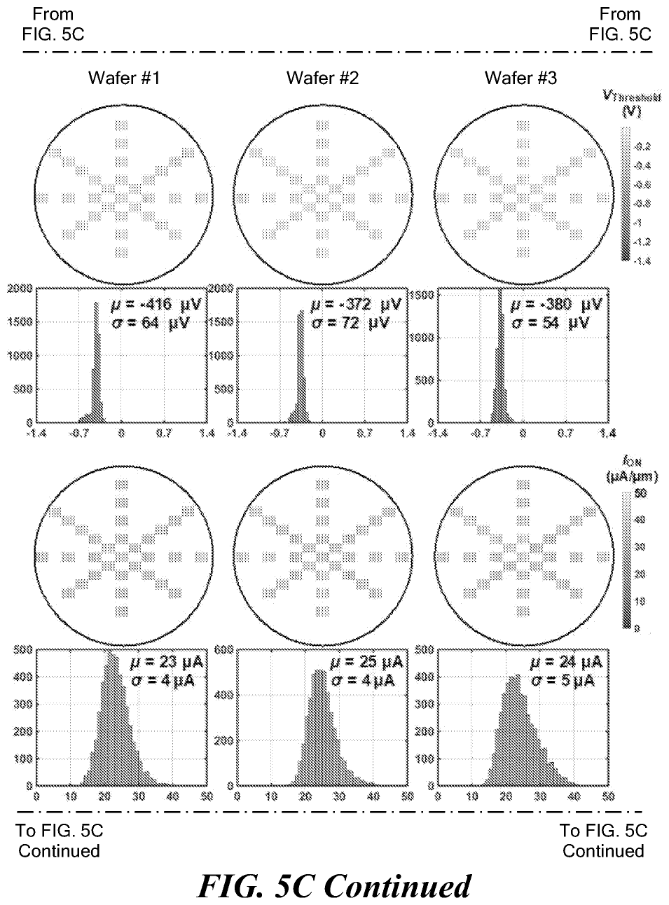

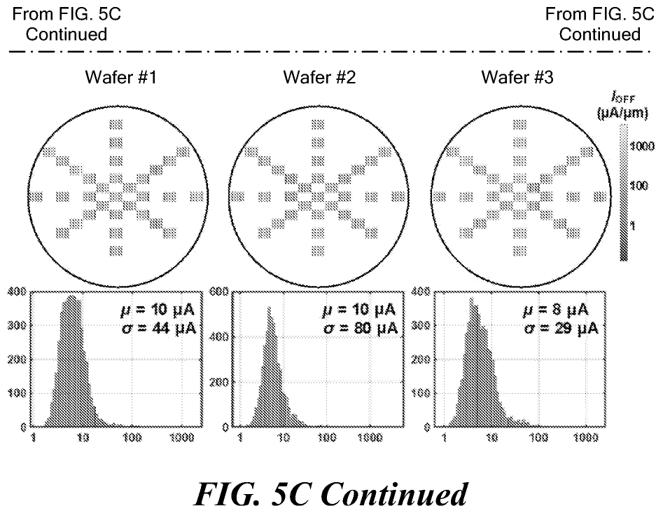

FIG. 5A shows a mapping of CNFET measurements across the 200 mm wafers). In FIG. 5A, a wafer map illustrating the die locations that are measured, showing wafer-scalable processing.

FIG. 5B illustrates typical I_{D}-V_{DS} and I_{D}-V_{GS} characteristics for the CNFETs.

FIG. 5C shows distributions for the threshold voltage (V_{T}), drive current (I_{ON}, I_{D} at V_{GS}=V_{DS}=−V_{DD}=1.4 V), off-state leakage current (I_{OFF}, I_{D} at V_{GS}=0V, V_{DS}=−V_{DD}), on-off ratio (I_{ON}/I_{OFF}, a metric for digital logic), and inverse sub-threshold slope (SS) for all of the CNFETs across the wafer. The results show tight distributions for all of these metrics, with reduced (and ideally, minimal) spatial dependence across the 200 mm wafer surface, demonstrating wafer-scale uniformity. FIG. 5C thus illustrates electrical characterization of CNFETs measured across 200 mm substrates and across three different wafers. Colormaps correspond with the extracted metric and location of the CNFET on the wafer substrate, each colored pixel corresponds to an individual CNFET. The distributions of the CNFET characteristics for each wafer are shown below the colormaps. Each distribution is comprised of 4,800 CNFETs (150 CNFETs measured across a die, and 32 dies across a wafer). Extracted metrics include threshold voltage, drive current, off-state current, on/off ratio, and inverse sub-threshold slope.

For instance, for one wafer characterized in FIGS. 5A-5C, the average threshold voltage is −416 mV with a standard deviation of 64 mV, the average on-off ratio is >4,000 with an average SS of ˜109 mV/dec, and the average drive current is >23 μA/μm taken at an average off-state current of <10 nA/μm. Importantly, this variability is not purely due to variations in CNT deposition, as it also includes intrinsic CNT variability (such as the presence of metallic CNTs, see the description herein below for a full discussion, including the impact of metallic CNTs and variability). Moreover, to demonstrate reproducibility, this test is repeated across multiple 200 mm wafers. The yield across all three wafers is 14,400 CNFETs/14,400 CNFETs, without removing any outliers for any reason (i.e. the total sample size of CNFETs across all three wafers is 14,400; CNFET yield was 14,400/14,000 without removing any outlier for any reason).

FIGS. 5A-5C thus illustrate electrical characterization of CNFETs fabricated across 200 mm substrates within a commercial silicon foundry.

### Methods:

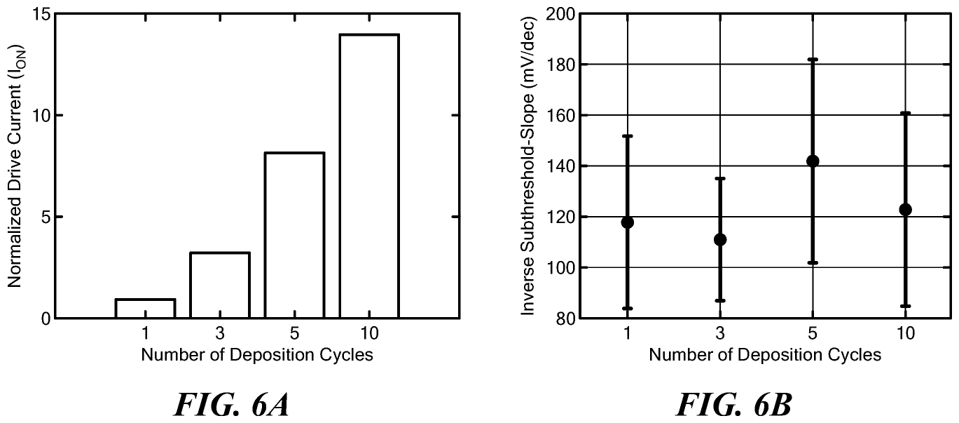

Local bottom gate CNFET fabrication: An example fabrication flow for the local bottom gate CNFETs is illustrated in FIG. 6. In this example embodiment, a 200 mm silicon wafer is the starting substrate. Due to the low-temperature fabrication of the entire CNFET fabrication flow, the silicon substrate can have pre-fabricated devices fabricated on the wafer including conventional BEOL interconnects. To fabricate the layer of CNFETs in the BEOL, the wafer substrate is planarized and metal gates are provided (e.g. metal gates may be patterned and defined through a Tungsten plug damascene process). After an optional planarization process (e.g. after the Tungsten plug is planarized, if necessary) a high-k gate dielectric (e.g. primarily HfO₂) is deposited (e.g. via an atomic layer deposition (ALD) process). Following the metal gate/high-k dielectric gate stack, the wafer goes through CNT incubation (as described elsewhere herein), and CNTs deposit uniformly across the wafer. In embodiments, CNTs deposited on the backside of the wafers may be removed by protecting the frontside of the wafer with photoresist and performing a backside clean. The source and drain metal contacts may be defined lithographically (or using any other suitable technique), and CNTs outside the CNFETs are removed (e.g. through an oxygen plasma etch while CNTs within the CNFETs are protected through lithographically defined photoresist).

CNT solution: The CNT solution contains 99.99% purified semiconducting CNTs suspended in toluene. The CNTs are synthesized through RF-plasma, and the CNT solution is a customized process derived from the Iso-sol-100 CNT solutions provided by NanoIntegris Inc. The semiconducting CNT purity is achieved through selective affinity of conjugated polymer for semiconducting CNTs, with process modifications throughout every step specifically to avoid introducing chemical contaminants throughout the entire CNT solution synthesis, sorting, and purification process.

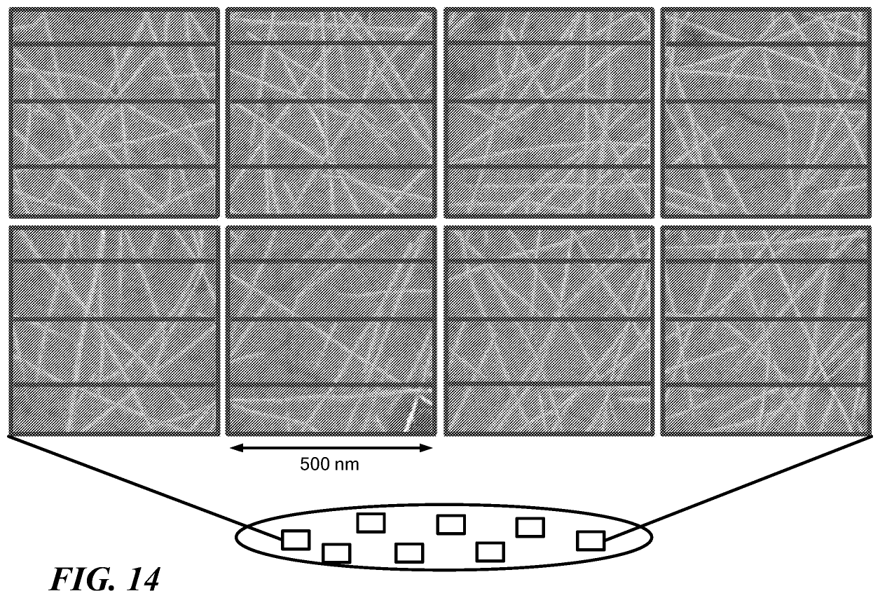

Imaging: To image the dense CNT depositions, in some embodiments, helium ion microscopy may be used. Helium ion microscopy has the benefit of enhanced contrast and resolution compared to SEM. In this example. all images are taken from a Zeiss Orion helium ion microscope (30 kV, 10 μm aperture). For each sample, 8 images were acquired over the surface of the substrate. For each image acquired, linear CNT density was counted at three locations on the image. For example, to characterize the CNT deposition process in FIG. 1B, 896 images were taken of 112 samples, and over 69,000 individual CNTs were counted. To characterize CNT density, we extract the linear CNT density, the number of CNTs per linear micron (see FIG. 14 for an example of extracting linear CNT density).

VLSI Design & Analysis: CNFET Energy Efficiency Vs. CNT Density

To quantify the energy efficiency of CNFET VLSI circuits as a function of CNT density, we leverage commercial electronic design automation (EDA) tools to design and analyze VLSI CNFET circuits. We develop industry-practice CNFET process design kits (PDKs) and standard cell libraries to perform synthesis and place-and-route of VLSI CNFET circuits, which we use to quantify total circuit energy consumption vs. clock frequency for a commercial-grade processor core at a 130 nm node CNFET technology (results shown in FIG. 2B). These results are then used to quantify the relative energy efficiency of CNFET circuits (using the Energy-Delay Product metric: EDP) as a function of CNT density (shown in FIG. 2C). In this section, we describe our VLSI design process to perform this analysis in 5 steps (corresponding to the flowchart in FIG. 2A).

Step 1 is to create layouts for CNFET library cells that will be used for synthesis and place-and-route, and to create the rules for parasitic extraction (to extract parasitic resistance and capacitance components from these layouts). For both of these tasks, we leverage an existing 130 nm node commercial silicon PDK, which includes 5 layers of metal (met1 through met5), as well as a local interconnect layer (underneath met1) to route to the silicon FET source/drain contacts, and to connect to the silicon FET gate layer. For the CNFET PDK, we add an additional metal layer for the source/drain contacts (beneath the local interconnect layer), and replace the silicon top-gate (located above the silicon FET channel) with a CNFET local back-gate (LBG) that is located beneath the active CNFET transistor layer. Accessing the CNFET LBG also requires an additional via layer to contact the back-gate from the source/drain metal layer (through the CNFET gate oxide layer).

Step 1a (in FIG. 2A) is to automatically convert the silicon-based library cell layouts into CNFET library cell layouts, using Standard Verification Rule Format (SVRF) commands for Calibre® to manipulate the Graphic Database System (GDS) representation of each library cell. There are 428 cells in total in this library, including both combinational and sequential logic. The silicon diffusion layer is mapped directly to the CNFET active layer, CNFET source/drain metal is added underneath the vias that contact the source/drain regions (and also in the shared source/drain regions of series FETs that do not instantiate any metal in the silicon-based libraries), and extra vias are added to contact the CNFET back gate (in the same regions that the gate contacts are located in the silicon-based libraries). No metal routing is changed from the local interconnect layer and above (met1 through met5), and since all the input/output/power pins are located on these layers, the same pin locations can be used for place-and-route tools (details in Step 5). Contacts to the bulk terminals of silicon FETs (i.e., “vpb” to the PMOS body and “vnb” to the NMOS body) are removed (since our CNFETs do not use a body contact), along with other superfluous layers (e.g., doping implants for NMOS and PMOS silicon FETs).

Step 1 b is to update the parasitic extraction (PEX) rules, so that the above CNFET layouts can be extracted to create netlists for circuit simulation (e.g., using Synopsys HSPICE® and Cadence Spectre®) that reflect CNFET circuits instead of silicon-based circuits. We begin with the interconnect technology file (.itf) provided with the silicon PDK, and then strip out all the layers below the local interconnect layer (as described in Step 1a). We then add the source/drain metal layer (100 nm thick) and CNFET gate layer below that (160 nm thick, as in the silicon PDK), with appropriate vias to connect these layers (with similar width/spacing requirements as the via between the local interconnect layer and met1). We also add spacer dielectrics between these layers (with similar dielectric constant profiles as in the silicon PDK), but with an additional high-K oxide that forms the CNFET gate (separating the source/drain from the gate). Once this layer stack is defined (.itf file format), we then use Calibre Xcalibrate® to generate SVRF rules that can be used in conjunction with the CNFET standard cell layouts to extract HSPICE/Spectre netlists with parasitics for each standard library cell. This extraction is performed in Step 2 (using Calibre®), together with another set of SVRF rules for identifying CNFETs from the layout polygons and instantiating them in the output netlists (hierarchical netlist extraction).

Step 3 is then to find the shift in CNFET threshold voltage (V_{T}) required to meet a target CNFET off-current density (I_{OFF}) for each combination of supply voltage (V_{DD}) and CNT density (in CNTs per micron); this step accounts for the convention that FET technology options offered by commercial foundries are often characterized by their off-current density (e.g., typical “high performance” or “low V_{T}” options have I_{OFF}=10 nA per micron of FET width (nA/micron), typical “regular V_{T}” options have I_{OFF}=1 nA/micron, and typical “low power” or “high V_{T}” have I_{OFF}=0.1 nA/micron). Here, we analyze an “RVT” CNFET option with I_{OFF}=1 nA/micron, although I_{OFF} can be another design variable swept during CNFET optimization. Inputs to Step 3 also include a SPICE-compatible compact model for CNFETs, which has been calibrated to experimental CNFET data from CNFETs fabricated with channel lengths ranging from >200 nm to <10 nm. This virtual source CNFET compact model (VSCNFET) incorporates non-ideal effects such as CNT-metal contact resistance, parasitic capacitance, CNT screening, and short channel effects (SCE) such as tunneling leakage current. Input parameters to the VSCNFET model include gate length, CNFET width, source/drain extension length, and CNFET contact length (all of which are provided in the extracted netlists from Step 2), as well as additional parameters such as CNT diameter and CNT-metal contact resistance. In this analysis, we input CNT diameter=1.2 nm, since that corresponds to the diameter of the CNTs in the fabricated CNFETs used to calibrate CNT mobility and injection velocity (in the VSCNFET model³⁹). We also input CNT-metal contact resistance (R_{C})=5.0 KOhm/CNT, as it has been experimentally demonstrated for CNFETs with contact length (L_{C}) of 90 nm (or larger)⁴⁰, which is suitable for 130 nm technology nodes. This “off-current re-targeting” step (as it is labeled in FIG. 2a) results in a unique threshold voltage shift for each of the 84 combinations of V_{DD} and CNT density that we analyze: V_{DD}={0.400, 0.450, 0.500, 0.550, 0.600, 0.650, 0.700}, and CNT density={250, 200, 166.7, 125, 100, 50, 25, 20, 12.5, 10, 5} CNT/micron. This threshold voltage shift to meet the I_{OFF} target (for each combination of V_{DD} and CNT density) is then used in subsequent steps for library characterization.

Step 4 is to perform CNFET library power/timing characterization (using Cadence Liberate®). In this step, we quantify timing/power of all cells as functions of input slew rate and output load capacitance, resulting in one industry-standard liberty (.lib) file for each combination of V_{DD} and CNT density; this .lib file is compatible with industry-practice EDA tools for logic synthesis and place-and-route. For example, for combinational logic library cells, the timing/power .lib file includes tables for output rise/fall delay/slew rate, energy consumption, and leakage power; sequential logic library cells also include tables for timing constraints for reduced (and ideally, minimum) pulse width, setup, and hold constraints. We configure Liberate® to use Cadence Spectre® as the circuit simulation engine, to generate .lib file for all 84 combinations of V_{DD} and CNT density.

Step 5 is to use the .lib files to perform physical synthesis of a 16-bit processor core, using Cadence Genus® and Cadence Innovus®. Since the CNFET layouts were converted from a silicon-based library, we are able to leverage the same layout exchange format (.lef) files that define the locations of all the pins for the standard cell macros (.macro.lef). Similarly, the since the back-end-of-line (BEOL) metal routing layers are the same as the silicon-based PDK (met1 through met5), use the same technology .lef file (.tech.lef), as well as the same BEOL parasitics extraction data generated using Cadence Techgen® (qrcTechFile). During physical synthesis, no timing constraints are set so that the Genus® will preferentially produce netlists with lower power consumption at the cost of larger delay (which is suitable for relative EDP comparisons, although additional EDP optimizations may be performed by optimizing targeting clock frequency during synthesis and place-and-route).

Upon completing Step 5, physical synthesis reports the power consumption for the 16-bit processor core (which sum of leakage power, switching power, and internal power), as well as the critical path timing delay, resulting in one overall power consumption value and one critical path delay value for each library (.lib file). Thus, for each library, we can compute the energy consumption per clock cycle (the product of power consumption and critical path delay) and the operating clock frequency (the inverse of the critical path delay); these are the 84 values plotted in FIG. 2B. Finally, for each of 12 different CNT densities, we select best energy-delay product (EDP) from each of the 7 different values of V_{DD}, resulting in 12 different values of EDP (one for each CNT density). These are then normalized the best EDP over all 12 points (which, in this analysis, corresponds to the best library at V_{DD}=0.650 V with CNT density=200 CNT/micron), which are plotted in FIG. 2C.

ACE: To control the evaporation rate and surface tension of the solvent during ACE, we control the vapor pressure of toluene in the ambient as the piece is undergoing the ACE process. By increasing the partial pressure of the solvent in the ambient, the evaporation rate of the solvent and the surface tension of the solvent decreases. Slowing the evaporation rate allows control over the time allowed for CNT deposition during ACE, allowing for longer incubation times at high concentrations, while maintaining the resulting uniformity. Reducing the surface tension of the solvent above the substrate also increases uniformity of deposition. As mentioned in the Main Manuscript, surface tension at the solvent-air interface causes droplet shrinkage during rapid evaporation and leads to non-uniform CNT deposition. Reducing surface tension by increasing the ambient partial pressure of toluene during ACE allows for the solvent to evaporate from the surface of the wafer in a controlled manner, maintaining uniform coverage over the entire substrate. Moreover, the ambient in ACE can be tuned to control the evaporation rate and surface tension: we have performed ACE in a range of ambient from toluene to ethanol to isopropyl alcohol.

### Dry-Cycling Electrical Characterization:

Referring now to FIG. 6, this figure shows additional electrical characterization of CNFETs fabricated using the dry-cycling process discussed in the main manuscript. While dry-cycling can result in substantially faster CNT deposition, each incubation cycle can result in CNTs depositing over previously-deposited CNTs (such layered deposition could lead to degraded electrostatic control by increasing the distance of the CNT from the gate, as well as CNT-CNT electrostatic shielding). To investigate if dry-cycling CNT deposition degrades CNFET performance, multiple wafers were fabricated with CNT depositions that have undergone different numbers of dry-cycles: one, three, five, and ten dry-cycling depositions. CNFETS were fabricated and measured across each of the wafers and the drive current and inverse sub-threshold slope were extracted from each wafer (results shown in FIGS. 6A, 6B).

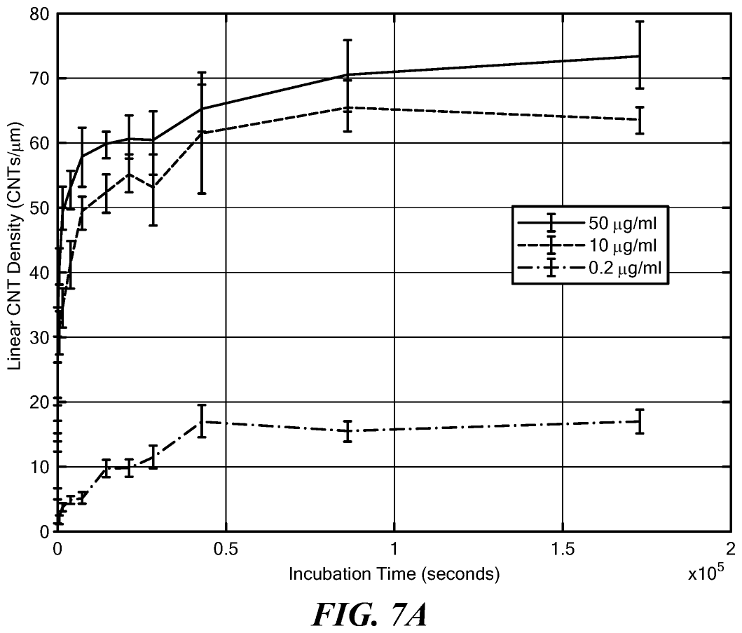

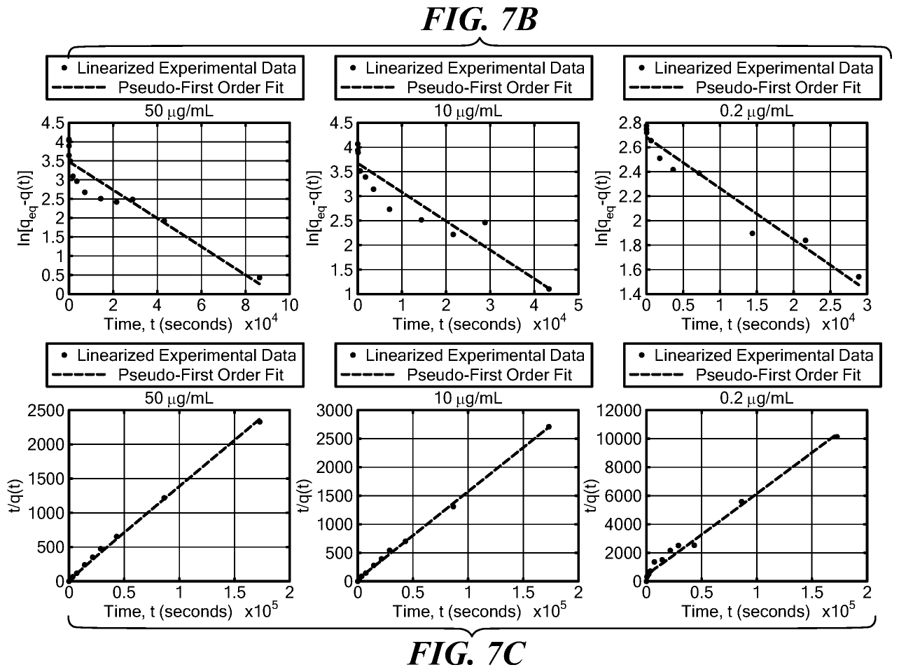

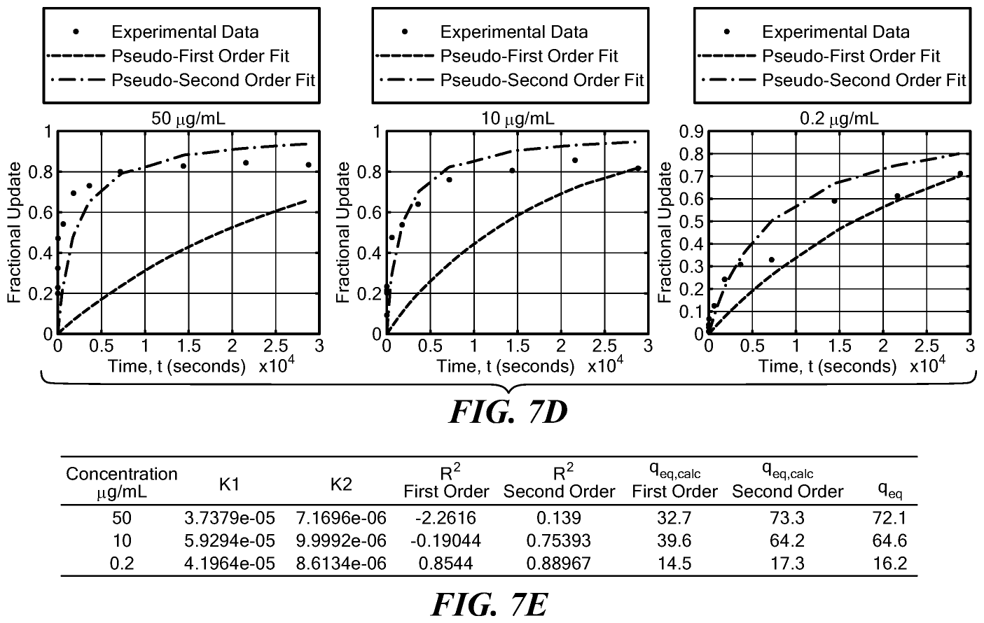

As can be seen in the FIGS. 7A-7E, the drive current follows the expected approximately linear increases with increasing number of dry-cycling depositions. Moreover, the average inverse sub-threshold slope for each wafer is approximately constant across all of the wafers, illustrating similar gate control regardless of the number of dry-cycling depositions. This has been observed in previous works and has been attributed to the fact that because the physical diameter of a CNT is ˜1 nm, the majority of the channel area is empty (e.g., even for densities of ˜100 CNTs/μm, ˜90% of the channel area is empty). As noted and characterized in prior works³, CNTs are flexible, and therefore are predicted to dry approximately flat on the substrate surface as capillary and Van der Waals pull the flexible CNTs close to the surface during the drying process.

While this work demonstrates critical advances for CNFET technologies, there are remaining challenges that should be addressed to realize the energy-efficiency benefits promised by CNFETs. For instance, CNT-metal contact resistance should be minimized to increase drive current at scaled supply voltages. Many prior works have studied CNT-metal contact resistance in detail, and several approaches (ranging from edge-contacts to metal-carbide contacts) have been proposed to improve contact resistance. Importantly, these approaches are largely independent of the CNT deposition technique, and thus process modifications for improved contact resistances can be integrated into future process flows with reduced effect (and ideally minimal or no effect) on the CNT deposition process. Additionally, contact resistance is a challenge for all scaled technologies (including silicon-based technologies), and therefore requires continued optimization regardless of the semiconductor technology. By initially integrating CNFETs at a mature technology node, the challenge of contact resistance is naturally reduced. In addition to contact resistance, the CNT-dielectric interface requires further optimization to reduce hysteresis and minimize threshold voltage variations. Several works have proposed a range of methodologies for minimizing interface traps at the CNT-dielectric interface through low-temperature anneals and cleans. As a last example, a portion of the CNFET variability is due to intrinsic CNT variations (e.g., CNT diameter and chirality). Many works are currently investigating improved solution-based CNT sorting to select tighter distributions of semiconducting CNTs.

### Kinetics/Nature of the Deposition Process/Thermodynamics:

FIG. 1B shows the measured linear CNT density as a function of time and CNT solution concentration for the incubation process. Here, we provide additional analysis leveraging two kinetic models: a pseudo-first order reaction model and a pseudo-second order reaction model. We extract kinetic parameters (including rate constants) and compare the models with the experimental measurements. The analysis is presented in FIGS. 7A-7E and is performed as outlined in Simonin et al., and Ho et al. We take linear density as a function of time for three different concentrations (while only one concentration is necessary to extract kinetic constants, we perform the analysis at three different concentrations). For each concentration, the experimental data undergoes a transform that linearizes it according to the rate law under consideration. If CNT deposition through incubation follows a pseudo-first order reaction, it is governed by equation 1:

ln[q_{eq}−q(t)]=ln q_{eq}−k₁t equation 1:

In which:
q_{eq} is the equilibrium CNT linear density (which we take as the linear CNT density after 48 hours of incubation time),
q(t) is the observed linear density as a function of time (t), and
k₁ is the pseudo-first order rate constant.

The pseudo-first order analysis is presented in FIG. 7B, where the experimental data is transformed and fit through linear least squares regression. From the best-fit line, we extract the predicted equilibrium linear CNT density (q_{eq,calc}, y-intercept=ln q_{eq,calc}) and the first order rate constant (slope=−k₁).

In FIG. 7C, a similar analysis is shown for a pseudo-second order process. If the experimental data observes a pseudo-second order kinetic process, it is governed by equation 2:

$$\frac{t}{q ( t )} = \frac{t}{{q}_{eq}} + \frac{1}{{k}_{2} {q}_{eq}^{2}} \qquad equation 2$$

in which k₂ is the pseudo-second order rate constant.

The pseudo-second order analysis is presented in FIG. 7C. We extract the predicted equilibrium linear CNT density

$$( slope = \frac{1}{{q}_{eq , calc}} )$$

and the pseudo-second order rate constant

$$( y - intercept = \frac{1}{{k}_{2} {q}_{eq , calc}^{2}} ) .$$

These extracted parameters are used to plot both models in the non-linear space with the experimental data in FIG. 7D. This may be used to calculate R-squared to evaluate the goodness-of-fit for both the pseudo-first order and pseudo-second order reactions. All extracted parameters for both kinetic models as well as the observed q_{eq} are displayed in FIG. 7E. While we observe the pseudo-second order model results in a slightly improved fit versus the pseudo-first order, neither pseudo-first or pseudo-second order result in very high-confidence fits (highest R-squared value observed=0.89). This is due to several reasons. For instance, we choose to analyze CNT deposition with state-of-the-art helium ion microscopy, as it provides ultra-high resolution imaging and is an excellent method for extracting linear CNT density—one significant metric for CNFET electrical performance (and the focus of this work). However, for studying adsorption kinetics, helium ion microscopy presents several limitations. First, the linear CNT density does not directly translate to the total number of CNTs adsorbed on a wafer (see discussion comparing aligned versus unaligned CNTs). Moreover, while we extract CNT linear density at 24 discrete sites across a substrate, the field of view is small (˜500 nm×500 nm) in order to resolve CNTs at such high CNT densities. This can lead to measurement noise as these discrete measurements are used to infer density over comparatively large substrates. Therefore, future studies specifically focusing on extracting kinetic parameters (and not CNT linear density for electrical characterization) would benefit from leveraging other analytical methods for measuring particle adsorption that provide large-area averaging (such as quartz crystal microgravimetry, QCM). While such characterization would not provide the electrical information provided in this work, it would benefit from less noise in measuring adsorption and thus provide improved fits for any kinetic model. Additionally, because CNT adsorption in incubation takes substantial time to reach equilibrium (>24 hours), performing the incubation process for even longer times (>48 hours) can provide more accurate measurements of equilibrium density to better inform the models.

Beyond measurement limitations, an additional explanation for the discrepancy between the models and experimental data is that the physics governing CNT adsorption is more complex than what is captured by the pseudo-first order and pseudo-second order models. For example, CNT-CNT interactions likely play an increasing role in adsorption rate over time as CNTs accumulate on the surface (a higher-order effect not taken into account in the analysis presented here). Further studies should investigate more comprehensive models that quantitatively describe the incubation process, deepening our understanding of CNT incubation and informing process design.

Thus, as described above, FIGS. 7A-7E illustrate kinetic analysis of CNT deposition.

FIG. 7A shows experimental data used in the kinetic analysis (3 different concentrations).

FIG. 7B illustrates a pseudo-first order analysis. Experimental data from each concentration is linearized according to equation 1 and fit with the least squares method.

FIG. 7C illustrates a pseudo-second order analysis. Experimental data is linearized according to equation 2 and fit with the least squares method.

FIG. 7D shows a comparison of pseudo-first and pseudo-second order fits. The experimental data is shown along with the computed pseudo-first and pseudo-second order models.

FIG. 7E is a table listing computed model parameters. The R-squared value for each model is computed from the plots shown in FIG. 7D. The pseudo-first order and pseudo-second order rate constants (K1 and K2, respectively), and the equilibrium density predicted by each model (q_{eq,calc}) are displayed along with the observed equilibrium density (q_{eq}).

Further Discussion of the Deposition Process:

As discussed above, the CNT deposition process adheres to behavior expected from an adsorption process. We used Langmuir adsorption theory to gain a base level understanding of what factors affect deposition rate and showed that we could exploit this intuition to greatly increase CNT linear density while simultaneously dramatically reducing processing time for CNT deposition. While this model was useful for informing a base-level intuition, incubation deviates from the idealities of Langmuir adsorption (i.e., Langmuir adsorption assumes the adsorbate is an ideal gas, all surface binding sites are identical, that the adsorption terminates at a perfect monolayer, etc.). Given this initial foundational work, future studies should further investigate the physical and chemical details of the incubation process, including whether the CNT deposition is dominated by physical adsorption, chemisorption or electrostatics, the entropy and enthalpy of binding, how particle-particle/particle-surface interactions affect binding, and how the driving force for binding changes as a function of linear CNT density on the surface of the substrate. In this work, we showed that even first-order insights into the physics of the CNT deposition process can be exploited to provide significant increases in efficiency for the incubation method. Continued work determining the molecular details of CNT deposition promises even greater strides in achieving high CNT density.

### CNT Density and Alignment Analysis:

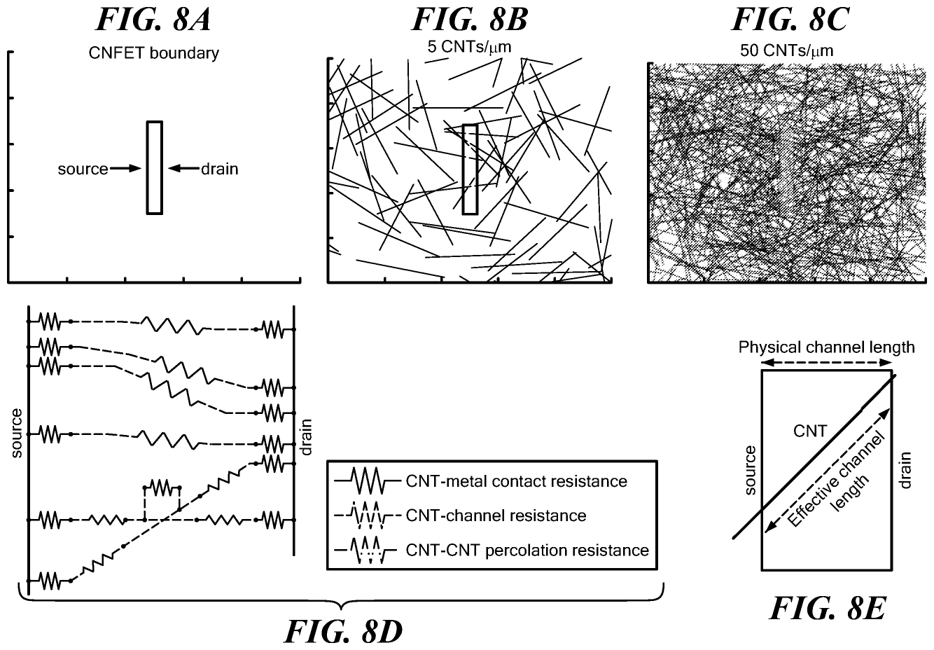

A detailed analysis was performed to correlate CNT density and alignment with resulting CNFET performance. To perform the analysis (see FIGS. 8A-8E), a graphical model of a CNFET was first physically formed. CNTs of a given length are randomly placed within a fixed area and assigned a rotation (for aligned CNTs, the rotations are all 0°, while for completely unaligned CNTs, the rotations are randomly assigned from a uniform distribution of alignment angles from 0-359°. After physically placing each CNT, the CNFET source and drain contacts are defined, and all CNTs outside of the active region of the CNFET (the CNFET channel region) are removed. The resulting physical model of the CNT is then converted into a circuit netlist, whereby each nanotube is replaced with a resistor. The resistance of any segment of CNT is assigned by taking the resistance per nanometer of a CNT and multiplying by the length of that segment. To account for percolation transport between crossing CNTs, additional resistors are then inserted at the nodes where the CNTs cross, and the additional resistor is assigned a percolation resistance. Both percolation resistance as well as the resistance per unit length of CNTs have been characterized and measured in prior works (refer to FIGS. 8A-8E for details). Lastly, contact resistances between the CNT and the CNFET source and drain contacts are inserted, completing the netlist model of the CNFET. Repeated monte-carlo trials for each combination of CNT density, channel length, channel width, etc., are performed to analyze both average channel conductivity (i.e., drive current) as well as variability and functional yield (functional yield is defined as a CNFET that has at least a single CNT bridging between the source and drain).

FIG. 2C shows the degradation in drive current comparing CNFETs with aligned versus unaligned CNTs. As noted in the manuscript, the degradation in drive current for unaligned CNTs is limited to ˜20% at scaled technology nodes. There are several factors that contribute to this ˜20% degradation:

Effective channel length: as illustrated in FIGS. 8A-8E, the effective channel length of an unaligned CNT is greater than the effective channel length for an aligned CNT (for an aligned CNT, the effective channel length is or corresponds to the physical channel length, the separation between the source and drain metal contacts). A larger effective channel length increases the channel resistivity, degrading drive current. However, this degradation is reduced (and ideally is minimal) as the entire series resistance of the CNFET is dominated by contact resistance rather than channel resistance (when the device is turned “on” by the gate electrode, particularly for scaled channel lengths).

Reduced CNT bridging probability: as the effective channel length increases, the probability that a finite-length CNT will bridge the entire source and drain decreases. However, as illustrated in FIG. 2C, this degradation is bounded by ≤20% (as it should be less than the total degradation) due to several reasons. First, for FETs with channel lengths significantly smaller than the CNT length, the vast majority of both aligned and unaligned CNTs bridge the entire channel length. Secondly, in the unaligned case, even if a CNT does not bridge the full physical channel length, the CNT can still contribute to total drive current due to percolation transport with any CNTs that is crosses. In contrast, aligned CNTs that do not bridge the full physical channel length do not cross other CNTs, and thus do not contribute any additional drive current. In fact, this is why for long channel lengths, unaligned CNTs actually provide more drive current than aligned CNTs. In the limit where the channel length exceeds the finite length of the CNTs, the aligned CNT drive current is zero (as no CNTs can possibly bridge the channel length), while the unaligned CNTs still provide drive current (albeit only through percolation transport). While we do not focus on such large geometry CNFETs, these devices have potential applications ranging from transparent displays to flexible electronics. Lastly, we compare aligned and unaligned CNTs given the same linear CNT density. We choose to normalize linear CNT density across the two cases as linear CNT density captures a significant factor in CNFET performance: the number of CNTs that bridge the source and drain contacts in the limit where the physical channel length approaches zero. Non-zero channel lengths introduce variability in the correlation between the linear CNT density and the number of bridging CNTs, but the values are still highly correlated at scaled channel lengths). If the CNTs are unaligned, more CNTs should be deposited on the wafer (compared to aligned CNTs) to realize the same linear CNT density. For example, for 1.6 μm long CNTs, it requires ˜40% more unaligned CNTs deposited on a substrate to achieve the same linear density as the aligned case.

Referring now to FIGS. 8A-8E, a framework for analyzing impact of CNT incubation on CNFET drive current is shown. In FIG. 8A a CNFET is initialized. FIG. 8B shows CNTs at a given length are randomly placed and assigned a rotation and Illustrates a trial with unaligned CNTs at a linear density of 5 CNTs/μm. FIG. 8C Illustrates a trial with 50 CNTs/μm. The black lines are CNTs that lie outside the channel region of the CNFET, while the red lines are segments of CNTs that cross through the channel region of the CNFET. The black lines are removed (as during CNFET fabrication, CNTs outside the active channel regions are etched), and a resistor network is formed using the remaining red lines. FIG. 8D Illustrates the resulting resistor network for the CNFET formed in FIG. 8B. The resistor network incorporates the CNT channel resistance (50 kΩ/μm), the CNT-metal contact resistance (10 kΩ), as well as the tunneling resistance between crossing CNTs (referred to as the “CNT-CNT percolation resistance”, 250 kΩ). These approximate values are taken from a range of literature. While the exact results are dependent on these values, the overall conclusions are similar over a range of resistance values. Definitions of “physical” channel length versus “effective” channel length are shown in FIG. 8E.

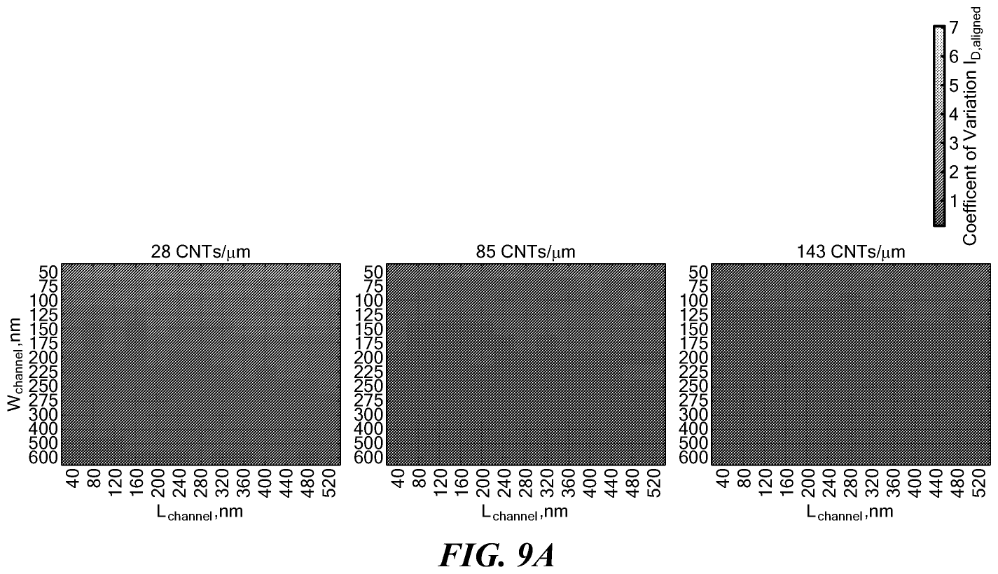

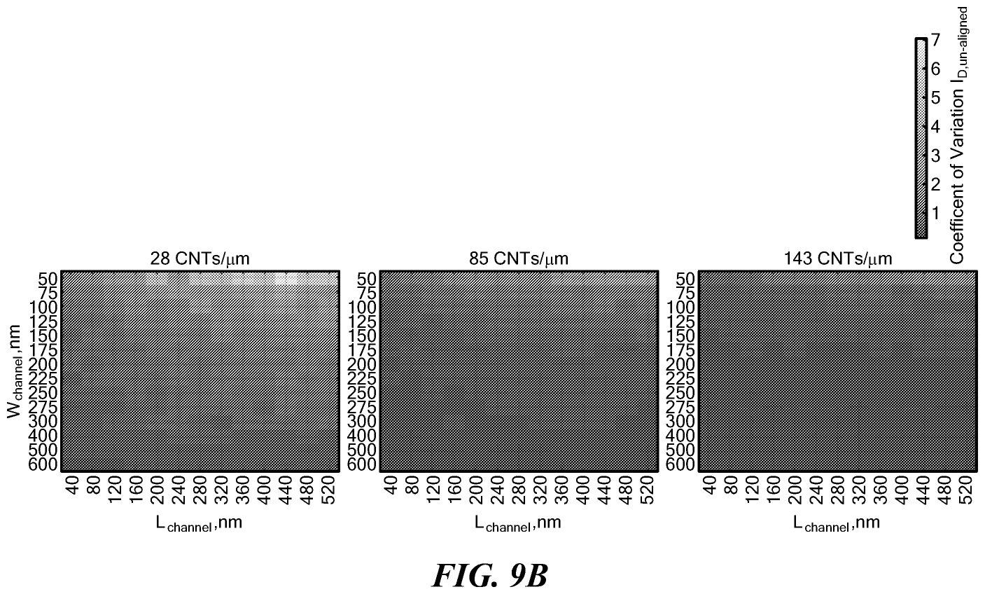

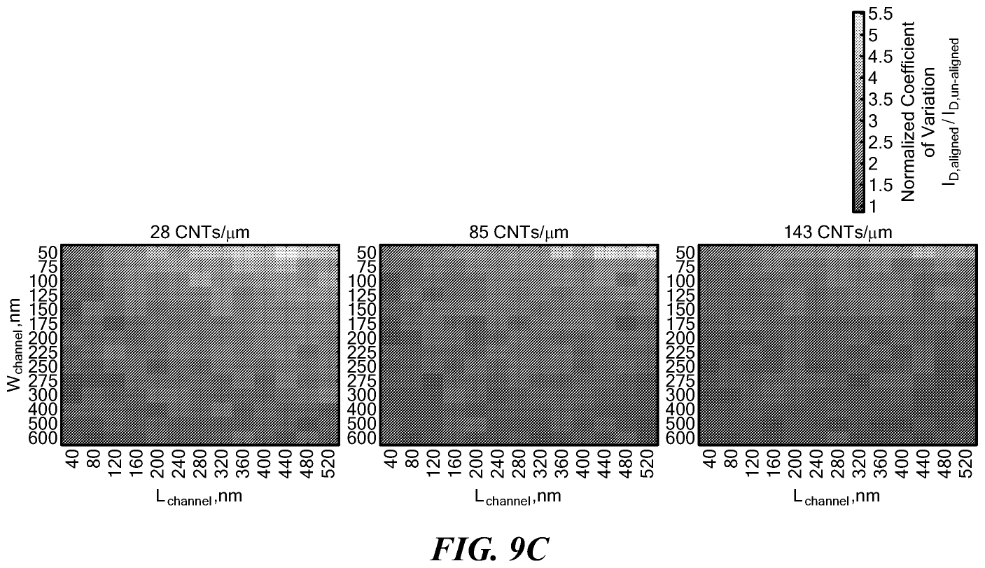

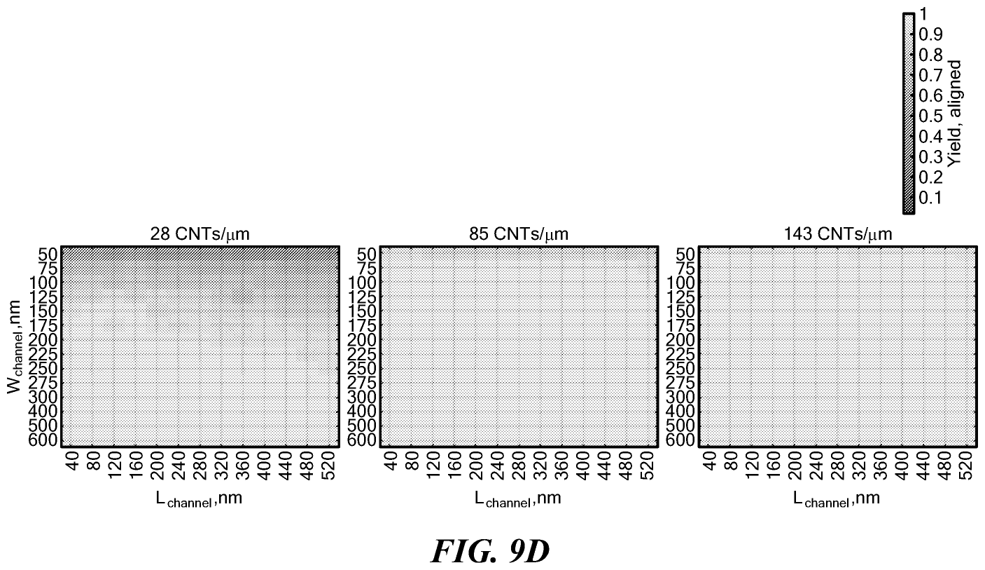

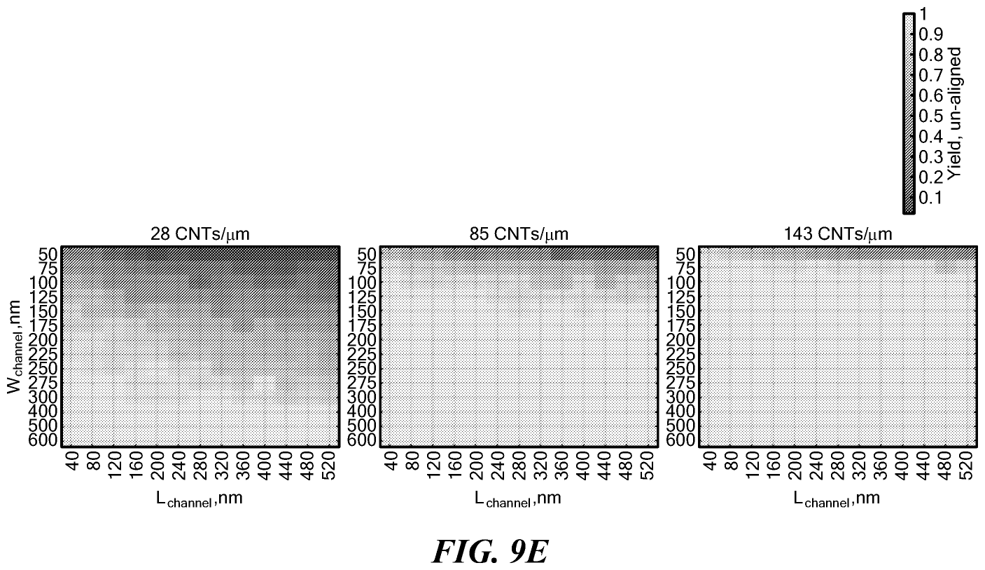

Mature 130 nm technology node BEOL integration. While CNFETs promise improved scalability beyond the limits of bulk semiconductors (such as silicon), establishing an advanced node process (particularly for an emerging technology) presents many challenges. By initially introducing commercial CNFET fabrication at a mature technology node, many technology-level challenges are naturally relaxed. For instance, the minimum width transistor at a mature technology node is greater than at a highly-scaled node. The increase in transistor width naturally provides averaging across devices, and therefore the CNFETs are substantially more robust to variations. For instance, FIGS. 9A-9E illustrate the variability and functional yield of unaligned CNFETs across a range of channel lengths and channel widths. As expected, increasing channel widths results in substantially reduced variability and improved functional yield. Moreover, other technology-level challenges, such as contact resistance, are naturally resolved by using a mature technology node since the contact length is greater in mature nodes than at advanced technology nodes.

After successfully establishing a mature technology node, foundries can leverage learning over decades of silicon-based scaling to continue scaling the CNFET technology node. Importantly, even before CNFETs are successfully scaled to more aggressive nodes, even a mature node CNFET technology can provide substantial system-level benefits and exciting opportunities. Because all CNFET fabrication (including our CNT deposition technique) are low-temperature (<400° C.), the CNFETs can be fabricated seamlessly in the BEOL directly over a starting silicon CMOS substrate. Such BEOL CMOS integration is not possible with conventional silicon CMOS, as the silicon FET fabrication requires >1000° C. for steps such as dopant activation annealing. The ability to integrate even a mature node CMOS technology in the BEOL can provide exciting new architectural and circuit-level innovations, supplementing advanced node silicon CMOS on the bottom layer. For instance, several works project that leveraging a mature node BEOL memory and BEOL CMOS (for memory access circuitry) over advanced node silicon CMOS can provide over an order of magnitude system-level EDP benefit versus conventional two-dimensional advanced node silicon CMOS, by providing ultra-dense and fine-grained connectivity between bottom-layer logic and on-chip main memory^{28,29}. Therefore, initial integration at a mature technology node (1) naturally relaxes technology-level requirements and enables for immediate technology integration today, (2) naturally provides a path for continued scaling benefits for future decades, and (3) mature node BEOL integration can already provide exciting circuit- and architectural-level benefits.

The question may be asked that while the incubation method does not control CNT alignment, do unaligned CNTs significantly increase device variability? Conventional thinking assumes that “random” CNT deposition and alignment introduces substantial variability and therefore cannot realize digital VLSI circuits. However, as illustrated in FIG. 9A-9E, the variability due to random CNT deposition and alignment is highly dependent on the CNFET geometry. As the channel width increases, variations are naturally averaged, reducing the impact of variations from unaligned CNTs. Moreover, as the channel length is also scaled, an increasingly high percentage of CNTs completely bridge the channel, also resulting in reduced variability. Importantly, while this implies (and the simulations in FIGS. 9A-9E confirm) that CNFETs with long channel lengths and scaled channel widths would have substantial variability, realistic CNFETs patterned at a given technology node would not exist with these geometries. Scaled minimum width transistors would only exist with simultaneously scaled channel lengths, and increasing the minimum channel length would likewise simultaneously result in an increasing minimum channel width. Within the regime of realistic CNFET geometries, the variability and yield due to CNT random alignment is negligible. Moreover, FIGS. 9A-9E also illustrates that by increasing CNT density (a goal for increasing EDP benefits as well), the variability and failures caused by unaligned CNTs are also naturally reduced. For instance, assuming a reduced CNT density of 28 CNTs/μm, the minimum width of a CNFET (W_{MIN}) with L_{CHANNEL}=200 nm would be upsized to W_{MIN}=400 nm to achieve functional yield of ˜100%. However, with increased CNT density to >100 CNTs/μm, any W_{MIN} can scale to L_{CHANNEL} and still maintain functional yield of ˜100% (FIG. 9E). Comparing FIGS. 9A, 9D (aligned variability and functional yield, respectively) and FIGS. 9B, 9E (unaligned variability and functional yield, respectively), it is clear that as expected, unaligned CNTs results in both increased variability and decreased functional yield. However, despite this cost, FIG. 9E illustrates that with sufficient CNT density, unaligned CNTs provide enough uniformity to avoid functional failures given realistic combinations of CNFET L_{CHANNEL} and W_{MIN}.

The question may also be asked, when CNTs deposit randomly, some of the CNTs overlap others—does this result in device performance degradation? As mentioned above, due to the small diameter of CNTs (˜1 nm) even at ˜100 CNTs/um, 90% of the channel area is empty. As observed experimentally, CNTs are flexible and the majority of the length of the CNT will still adhere against the wafer substrate as it dries due to capillary and Van der Waals forces. However, for regions where the CNTs are overlapping or not in intimate contact with the substrate, the CNT conductivity within that section of the CNT will be degraded, as that segment of CNT is both further from the gate and suffers from CNT-CNT electrostatic shielding. Decreasing the conductivity of the CNTs in the regime that the CNTs overlap results in <5% degradation in drive current (as the CNT series resistance is dominated by the CNT-metal contact resistance and not the CNT resistance through the channel itself).

Moreover, FIGS. 6A, 6B show experimental measurements of CNFETs fabricated after performing one, three, five, and ten dry-cycling depositions. This dry-cycling deposition process likely results in some overlapping CNTs in some regions of the CNFET. However, despite the increasing number of overlapping CNTs for increasing number of dry-cycling depositions, the drive-current follows approximate linear scaling versus the number of dry-cycling depositions, and the inverse-subthreshold slope for the CNFETs remains approximately constant, demonstrating consistent gate control of the CNTs through the channel despite the overlapping CNTs.

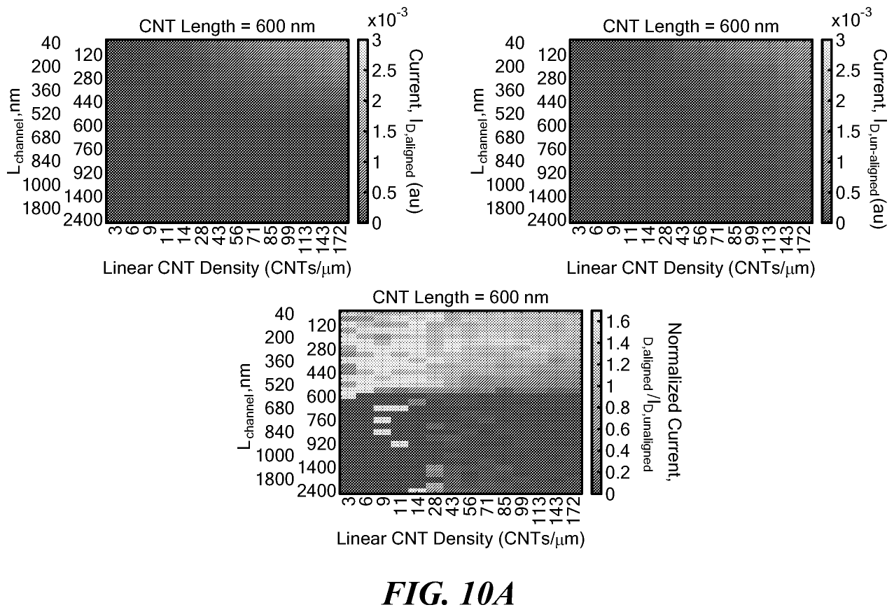

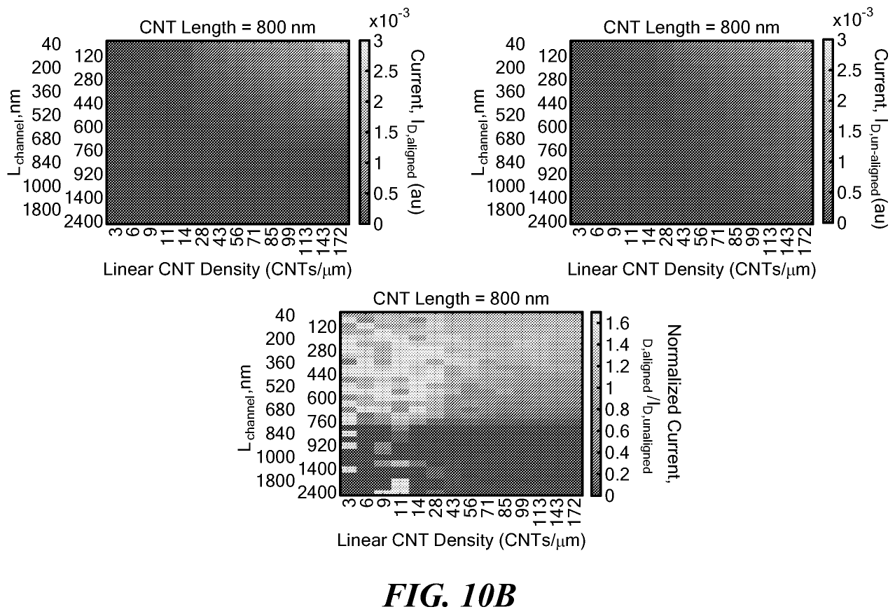

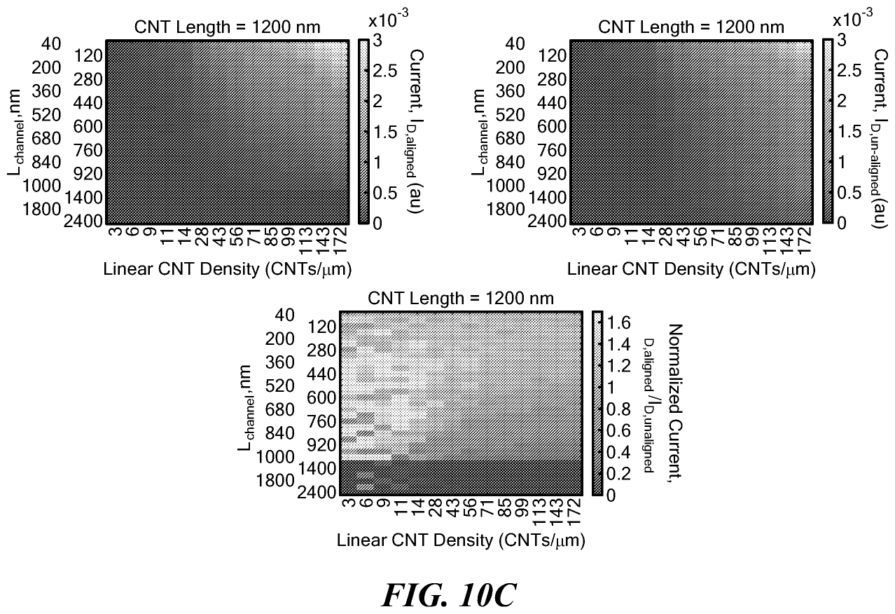

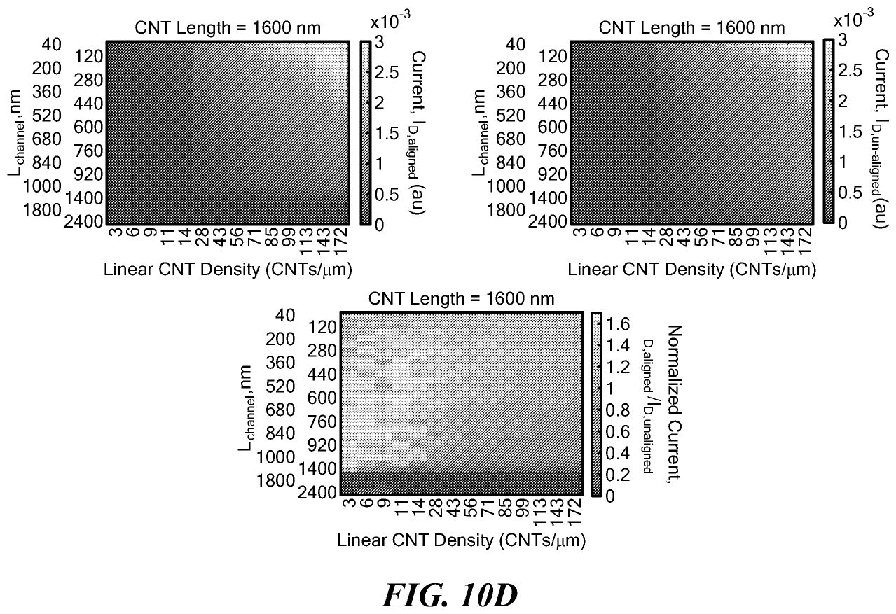

The question may also be asked, is it desirable to have the longest CNTs possible? And related: how does CNT length impact significant metrics? As illustrated in FIG. 10, as the length of the CNTs increase, so too does the drive current. This is primarily a function of increasing the linear CNT density for the same number of CNTs deposited per-unit-area. With increased CNT length, the effective linear CNT density also increases, which is beneficial and results in reduced variability, reduced failures, and increased drive current. However, even CNT lengths of 1.6 μm (which are commercially available and the CNTs used in this work) provide sufficient length for bridging scaled physical channel lengths.

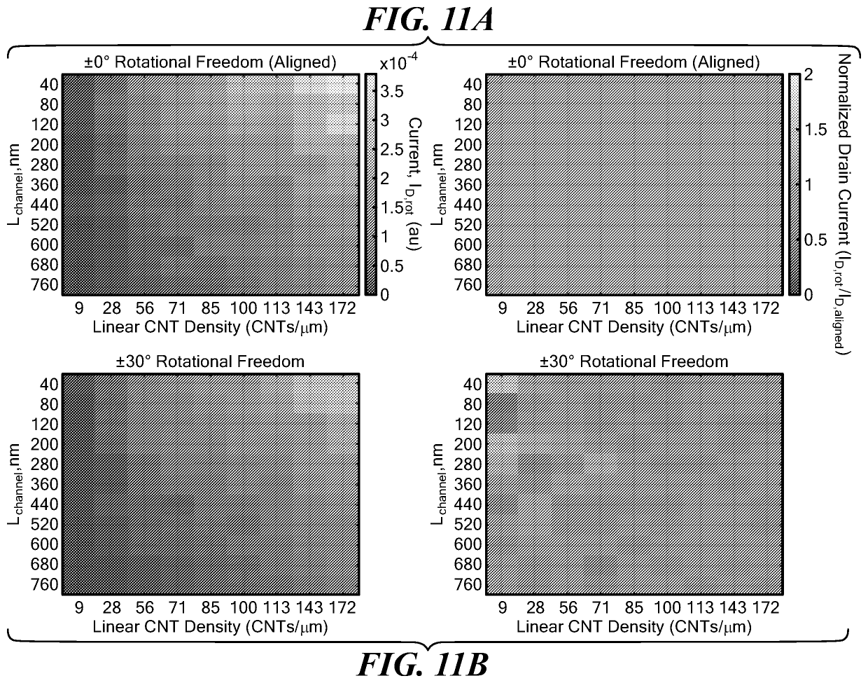

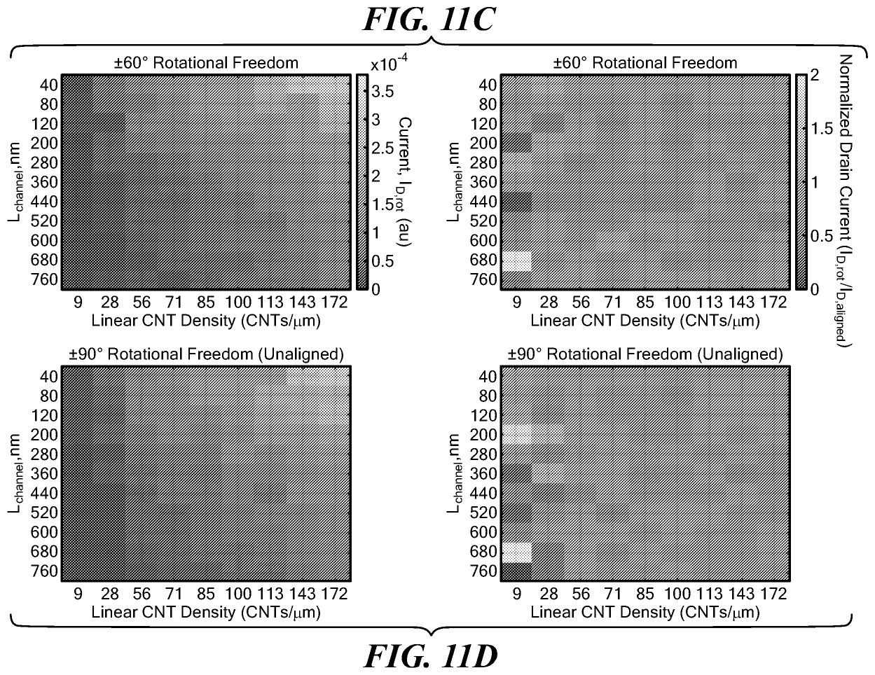

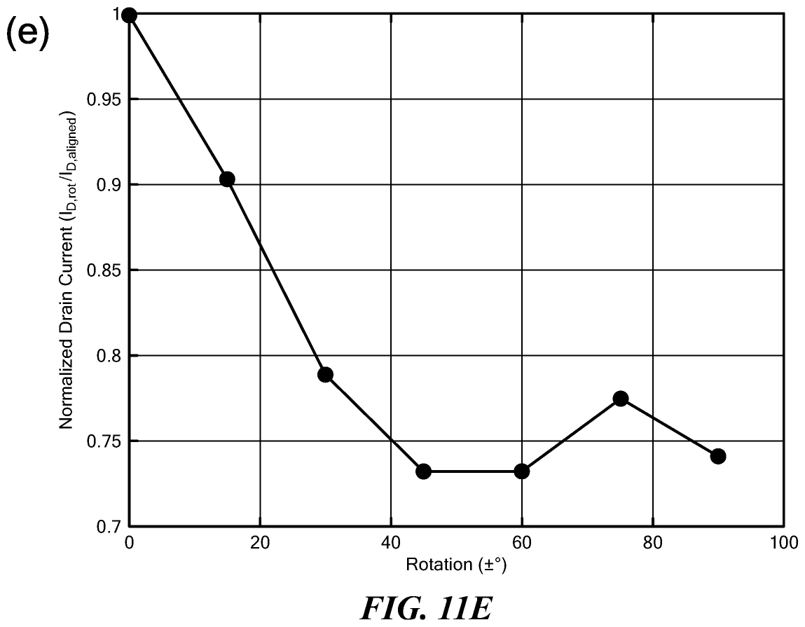

FIG. 11 shows the trade-off between degree of unalignment and degradation in drive current (i.e. the trade-off between the degree of alignment and the CNFET drive current). In this analysis, CNTs in the channel of the simulated device are allowed orientations that deviate by varying degrees from perfect alignment (which we define as 0°), following a uniform distribution (for instance, 15° means the CNT alignment angles fall in a uniform distribution between ±15° off from the perfectly aligned case). Several points are illustrated in FIG. 11. First, in the worst-case scenario, completely unaligned CNTs result in a ˜20% degradation in drive current compared to perfectly aligned CNTs. Secondly, as the degree of mis-alignment decreases, the degradation in drive current also decreases. However, quasi-aligned CNTs provide only a small, if any, benefit compared to randomly aligned CNTs. Reducing the degradation in drive current in half (from ˜20% to 10% degradation in drive current) requires reducing the degree of misalignment more than a half: from +−90° down to +−15°. Therefore, while achieving improved CNT alignment should be a goal for future work, other primary objectives such as improving CNT-metal contact resistance could provide larger gains in CNFET performance during these initial stages of development.

The question may also be asked, what about the other obstacles facing CNT technologies such as metallic CNTs or realizing complementary (CMOS) CNFETs? While the presence of metallic CNTs and realizing CMOS CNFETs had been major challenges in the field of CNFETs for over a decade, recent works have experimentally demonstrated techniques for overcoming these challenges. For metallic CNTs, work by Hills et al., developed a new circuit-design technique named DREAM (Designing Resiliency Against Metallic CNTs) that enables digital VLSI circuits to be designed with a purity of only 99.99% semiconducting CNTs (without this technique, the required semiconducting purity for digital VLSI circuits is >99.999999%)³⁰. Critically, 99.99% semiconducting CNTs can be purchased commercially already today (and was used in this work). As can be seen from the experimental characterization of the CNFETs in FIG. 5, average on-off ratio is >4,000, and average leakage current is ˜10 nA: sufficient values for realizing digital VLSI circuits.

Similarly, for CNFET CMOS, a new methodology named MIXED (Metal Interface crossed with Electrostatic Doping) enabled the first demonstration of wafer-scale and robust CNFET CMOS. This work experimentally demonstrated a VLSI-compatible and silicon-CMOS compatible method for doping CNTs in order to realize symmetric complementary n-type and p-type CNFETs. Moreover, complete CNFET CMOS digital systems, ranging from analog and mixed-signal circuits to 6T Kbit SRAM arrays to monolithic three-dimensional imagers to a RISC-V microprocessor have all be experimentally demonstrated leveraging this MIXED process. Thus, while progress with metallic CNTs and improved CNT doping should continue to be pursued, recent progress has demonstrated a promising pathway for overcoming these challenges.

### Commercial Manufacturing Facility:

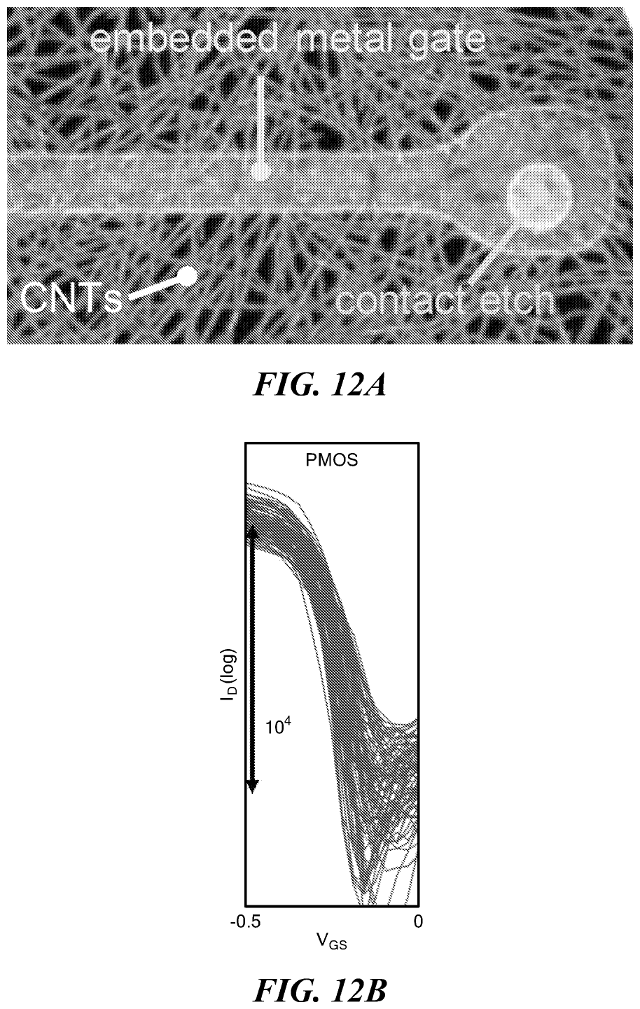

In addition to the 200 mm silicon foundry results presented in the manuscript, we also establish a pilot CNFET line with a commercial silicon manufacturing facility, Analog Devices, Inc. (ADI). The CNFET fabrication process follows a similar flow as described in Methods. Scanning electron microscopy images of fabricated CNFETs, as well as typical I_{D}-V_{GS} characteristics from a set of CNFETs measured across a wafer, are shown in FIGS. 12A, 12B.

FIGS. 12A, 12B illustrate CNFETs fabricated within the commercial silicon manufacturing facility. FIG. 12A is a scanning electron microscopy image of CNT incubation performed over a local bottom gate (Tungsten metal damascene process) and high-k gate dielectric. FIG. 12B is a plot of overlaid I_{D}-V_{GS} measurements of 150 typical CNFETs, achieving on/off ratio of ˜10⁴.

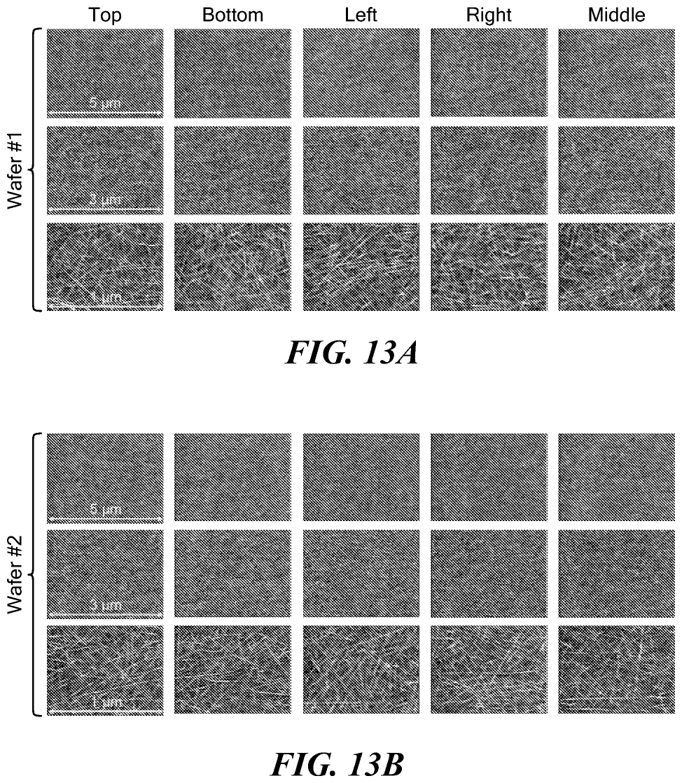

FIGS. 13A, 13B show typical images of CNT incubation from the silicon manufacturing foundry. Images are taken across multiple 200 mm wafers illustrating uniformity and reproducibility.

FIG. 14 illustrates the process of measuring linear CNT density: the number of CNTs per linear micron.

In the foregoing detailed description, various features of the described concepts are grouped together in one or more individual embodiments for streamlining the disclosure. This method of disclosure is not to be interpreted as reflecting an intention that the claimed concepts described herein require more features than are expressly recited in each claim. Rather, inventive aspects may lie in less than all features of each disclosed embodiment.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to

the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to, “such as, for example, “a first element selective to a second element,” means that the first element can be etched and the second element can act as an etch stop.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described implementations which serve to illustrate various concepts, structures, and techniques which are the subject of this disclosure, it will now become apparent to those of ordinary skill in the art that other implementations incorporating these concepts, structures, and techniques may be used. Accordingly, it is submitted that that scope of the patent should not be limited to the described implementations but rather should be limited only by the spirit and scope of the following claims.

1. A process for fabricating a carbon nanotube field-effect transistor (CNFET), the process comprising:
(a) submerging a substrate in a carbon nanotube (CNT) solution;
(b) removing the substrate from the CNT solution;
(c) drying the substrate;
(d) defining a gate region in the substrate;
(e) depositing a gate dielectric in the defined gate region;
(f) depositing a carbon nanotube (CNT) on a surface of the substrate;
(g) providing source and drain electrodes contacts on the surface of the substrate having the CNTs disposed thereon so as to define channel regions of a carbon nanotube field effect transistor (CNFET); and
(h) removing CNTs outside the channel regions of the CNFET.

2. The process of claim 1 wherein defining a gate region in a substrate comprises defining a local bottom gate region in the substrate.

3. The process of claim 2 wherein defining a local bottom gate region in the substrate comprises defining a local bottom gate region in the substrate via an additive process.

4. The process of claim 2 wherein defining a local bottom gate region in the substrate comprises defining a local bottom gate region in the substrate via a Tungsten damascene process.

5. The process of claim 1 wherein depositing a gate dielectric in the defined gate region comprises depositing a high-k gate dielectric in the gate region comprises depositing a high-k gate dielectric in the gate region through atomic layer deposition (ALD).

6. The process of claim 5 wherein depositing a high-k gate dielectric in the gate region comprises depositing a high-k gate dielectric in the gate region via an atomic layer deposition (ALD) process.

7. The process of claim 1 wherein depositing a carbon nanotube (CNT) on a surface of the substrate comprises depositing a CNT on a surface of the substrate via incubation.

8. (canceled)

9. (canceled)

10. (canceled)

11. (canceled)

12. A method for improving CNT deposition through an artificial concentration through evaporation (ACE) methodology, the method comprising:
(a) depositing CNT solution at low concentration on a substrate;
(b) allowing the solvent to incubate under a solvent-rich ambient wherein as the solvent evaporates, the remaining solution increases in CNT concentration.

13. The method of claim 12 wherein depositing CNT solution at low concentration on a substrate comprises at least one of:
depositing the solution on top of the wafer; or
submerging the wafer within a tank of solution and subsequently withdrawing the wafer from the tank of solution thereby leaving a small volume of solution that completely covers the substrate surface.

14. The method of claim 14 wherein submerging the wafer within a tank of solution and subsequently withdrawing the wafer from the tank of solution comprises submerging the wafer within a tank of solution and immediately withdrawing the wafer from the tank of solution.

15. A structure comprising:
a substrate; and
a plurality of carbon nanotubes (CNTs) deposited uniformly over the substrate.

16. The structure of claim 15 where the substrate is a ≥200 mm substrate.

17. (canceled)
